(19) United States
(12) Patent Application Publication
(10) Pub. No.: US 2026/0051349 A1
(43) Pub. Date: Feb. 19, 2026

(54) SEMICONDUCTOR MEMORY DEVICE

(71) Applicant: Unisantis Electronics Singapore Pte. Ltd., Singapore (SG)

(72) Inventors: Takashi OHSAWA, Tokyo (JP); Masakazu Kakumu, Tokyo (JP); Nozomu Harada, Tokyo (JP)

(21) Appl. No.: 19/299,003

(22) Filed: Aug. 13, 2025

(30) Foreign Application Priority Data
Aug. 14, 2024 (JP) 2024-135252

(51) Int. Cl. G11C 11/4091; G11C 5/06; G11C 11/406; G11C 11/408; G11C 11/4096; H10B 12/00

(52) U.S. Cl. CPC G11C 11/4091; G11C 5/063; G11C 11/406; G11C 11/4085; G11C 11/4096; H10B 12/20

(57) ABSTRACT

Provided is a semiconductor memory device that stores data by accumulating multiple carriers in an electrically floating body of a metal-oxide-semiconductor field-effect transistor. A plate line capacitively-coupled to the floating body is routed parallel to a word line in an isolated fashion for every word line so that, by applying voltage to the plate line, the multiple carriers are collectively erased along the word line. A writing operation of the semiconductor memory device is executed by causing sense amplifier circuits to read and latch data from cells along a selected word line, isolating bit lines from the sense amplifier circuits to erase data from the cells by applying voltage to the plate line belonging to the word line while simultaneously writing data into the sense amplifier circuits from the outside, and injecting multiple carriers into the bodies of the cells according to the states of the sense amplifier circuits.

### CROSS REFERENCES TO RELATED APPLICATIONS

This application claims priority to JP2024-135252, filed Aug. 14, 2024, the entire content of which is incorporated herein by reference.

### BACKGROUND OF THE INVENTION

### 1. Field of the Invention

The present invention relates to memory devices using semiconductor elements.

### 2. Description of the Related Art

In recent years, the development of LSI (large-scale integration) technology has demanded higher integration, higher performance, lower power consumption, and enhanced functionality of memory devices that can be installed in logic circuits using semiconductor elements.

A widely used example of a memory of an integrated circuit is a dynamic random access memory (DRAM). In order to enhance the density of a DRAM, there are disclosed a DRAM using an SGT structure extending perpendicularly to the upper surface of a semiconductor substrate (e.g., see Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991), and see H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)) and a capacitor-less DRAM memory cell constituted of a single MOS transistor (e.g., see T. Ohsawa, K. Fujita, T. Higashi, Y. Iwata, T. Kajiyama, Y. Asano, and K. Sunouchi, “Memory Design Using a One-Transisitor Gain Cell on SOI”, IEEE Journal of Solid State Circuits, Vol. 37, No. 11, pp. 1510-1522 (2002); J. Wan, L. Rojer, A. Zaslavsky, and S. Critoloveanu: “A Compact Capacitor-Less High-Speed DRAM Using Field Effect-Controlled Charge Regeneration”, Electron Device Letters, Vol. 35, No. 2, pp. 179-181 (2012); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006)ⱼ and E. Yoshida: “A Capacitorless 1T-DRAM Technology Using Gate-Induced Drain-Leakage (GIDL) Current for Low-Power and High-Speed Embedded Memory”, IEEE IEDM (2006)). The latter is commonly called “1T DRAM”. For example, logic data “1” is written by retaining some or all of holes, among holes and electrons generated by impact ionization within a channel due to electric current between the source and the drain of an n-channel MOS transistor, in the channel. Then, logic data “0” is written by removing the holes from the channel.

For example, the writing of the logic data “1” (with a lower threshold voltage) is performed by retaining, in a floating body, some or all of the holes, among the holes and electrons generated by impact ionization within the channel due to electric current between the source and the drain of the n-channel MOS transistor formed in an SOI (silicon on insulator). Then, the writing of the logic data “0” (with a higher threshold voltage) is performed by extracting the holes from the body. Originally, a “0” write is implemented by increasing the gate voltage of a cell connected to a word line and then setting the potential of a bit line connected to the drain of the cell to a negative potential (where the source potential of the cell is defined as 0 V). In this method, however, in order to prevent holes from being extracted from the body of another cell connected to the same bit line, a non-selected word line has to be set to a negative potential, and the voltage of the body of a non-selected cell has to be reduced to a sufficiently low voltage. Thus, when a “1” write is to be performed by increasing the bit-line potential, the voltage of the gate, as viewed from the drain, becomes a large negative absolute value, thus causing the holes to flow into the body of the “0” data cell due to GIDL (gate induced drain leakage). This is problematic in terms of an issue (bit-line disturb) where the cell in the “0” state is turned into a “1” state.

In order to solve this problem, there is proposed a “0” write method involving raising the voltage of a plate capacitively-coupled to the body to extract the holes from the body. For example, a cell called a key shaped floating body memory (KFBM) has a structure in which a tall silicon pillar is surrounded on all sides by a thin insulating film and is covered with a plate electrode (e.g., see US 2023/0077140 A1 and M. Kakumu, Y. Li, K. Sakui, N. Harada, “Fully bulk CMOS compatible Key Shape Floating Body Memory (KFBM)”, Memories-Materials, Devices, Circuits and Systems, 4 (2023) 100061). When writing “0” data, the plate electrode is set to a high value, so that holes can be extracted from the bodies of all cells within the cell array. Since this “0” write does not require selectivity, the word lines do not have to be set to a negative potential and may be 0 V during the “0” write. Therefore, the bit-line disturb issue, which is originally problematic in the cells during the “1” write, is significantly improved.

However, in this memory device using memory elements, there still remains a problem in that there is no clear method for executing a writing operation and a refreshing operation.

### SUMMARY OF THE INVENTION

An object of the present invention is to achieve a random access memory by providing new writing and refreshing operations as well as a circuit and a driving method thereof for implementing these operations.

In order to solve the aforementioned problem, a memory device using semiconductor elements according to the present invention has a configuration in which a plate line extends parallel to a word line and commonly to a cell belonging to a page selected based on the word line, and in which the plate line is connected to an electrode capacitively-coupled to a floating body of a MOSFET constituting a memory cell. The word line is activated, and data stored in the memory cell belonging to the page is read and latched by a sense amplifier circuit. Then, a bit line and the sense amplifier circuit are disconnected from each other. The plate line belonging to the page is activated, and multiple carriers are removed from the floating body of the memory cell belonging to the page. At the same time, the latch state of the sense amplifier circuit is inverted by using data input from a data line, where necessary. Subsequently, the cell belonging to the page is programmed (i.e., multiple carriers are injected) in accordance with the latch state of a new sense amplifier circuit, thereby implementing writing. A refreshing operation is implemented based on a similar operation except for the aforementioned operation in which “the latch state of the sense amplifier circuit is inverted by using data input from a data line, where necessary”.

One aspect of the present invention provides a semiconductor memory device comprising:
a plurality of memory cells (e.g., cells connected to common WL in FIG. 1) arranged in a first direction (e.g., direction in which WL extends in FIG. 1) on a substrate (e.g., 14 in FIG. 17A to FIG. 17F) in plan view to constitute a page,
   wherein each memory cell includes
   an electrically-floating semiconductor body (e.g., 8 in FIG. 17A to FIG. 17F),
a first impurity region (e.g., 9 in FIG. 17A to FIG. 17F) that is in contact with one of side surfaces of the semiconductor body and connects with a source line, and a second impurity region (e.g., 19 in FIG. 17A to FIG. 17F) that is in contact with another one of the side surfaces of the semiconductor body and connects with a bit line,
a gate insulating film (e.g., 15 in FIG. 17A to FIG. 17F) that is in contact with the semiconductor body,
   a first gate conductor layer (e.g., 1 in FIG. 17A to FIG. 17F) that forms a transistor together with the semiconductor body, the first impurity region, and the second impurity region and that is in contact with the gate insulating film and is connected to a word line (e.g., WL in FIG. 1), and
   a second gate conductor layer (e.g., 3 in FIG. 17A to FIG. 17F) that is in contact with the gate insulating film at a location different from the first gate conductor layer and that is connected to a plate line (e.g., PL in FIG. 1);
a sense amplifier circuit (e.g., current load circuit and latch circuit in FIG. 4) that amplifies and latches a signal read from the memory cell connected to the bit line via a first switching circuit (e.g., SW3ⱼ, SW4ⱼ, SW3ⱼ₊₁, SW4ⱼ₊₁, etc. in FIG. 4)ⱼ and
a data line (e.g., DQ, /DQ in FIG. 4) connected to the sense amplifier circuit via a second switching circuit (e.g., SW1ⱼ, SW2ⱼ, SW1ⱼ₊₁, SW2ⱼ₊₁, etc. in FIG. 4).

A writing operation includes activating the word line and turning on the first switching circuit to cause the sense amplifier circuit to amplify and latch data stored in the memory cell, blocking the first switching circuit, selecting the plate line to erase the memory cell while simultaneously turning on the second switching circuit to input data from the data line to the sense amplifier circuit and change a latch state of the sense amplifier circuit, and subsequently programming the memory cell in accordance with the latch state of the sense amplifier circuit (e.g., timing chart in FIG. 13).

In the semiconductor memory device, a refreshing operation preferably includes activating the word line and turning on the first switching circuit to cause the sense amplifier circuit to amplify and latch the data stored in the memory cell, blocking the first switching circuit and selecting the plate line to erase the memory cell, and subsequently programming the memory cell in accordance with the latch state of the sense amplifier circuit (e.g., timing chart in FIG. 14).

In the semiconductor memory device, it is preferable that a word-line driver circuit (e.g., WL drivers in FIG. 16) connected to one end of the word line extending in the first direction in plan view is selectively activated by a row address selector circuit (e.g., row decoder in FIG. 16), a plate-line driver circuit (e.g., PL drivers in FIG. 16) connected to one end of the plate line is located in an opposite direction of a memory cell array from the word-line driver circuit relative to the first direction, and the plate-line driver circuit is selectively activated by the word line.

In the semiconductor memory device, it is preferable that the sense amplifier circuit (e.g., S/Aⱼ in FIG. 4) includes
a first sense node (e.g., SNLⱼ in FIG. 4) isolated from a first bit line (e.g., BLLⱼ in FIG. 4) via a first switching element (e.g., SW3ⱼ in FIG. 4),
a second sense node (e.g., SNRⱼ in FIG. 4) that is located opposite the first bit line relative to the sense amplifier circuit (e.g., S/Aⱼ in FIG. 4) or that is isolated from another second bit line (e.g., BLRⱼ in FIG. 4) adjacent to the first bit line (e.g., BLLⱼ in FIG. 4) via a second switching element (e.g., SW4ⱼ in FIG. 4),
a current load circuit (e.g., “current load circuit” belonging to S/Aⱼ in FIG. 4) that causes electric current to flow through the first and second bit lines via the first and second sense nodes and the first and second switching elements,
a latch circuit (e.g., “latch circuit” of S/Aⱼ in FIG. 4) that amplifies and latches a potential difference between the first and second sense nodes,
a first programming circuit (e.g., “programming circuit” connected to BLLⱼ in FIG. 4) that applies voltage to the first bit line,
a second programming circuit (e.g., “programming circuit” connected to BLRⱼ in FIG. 4) that applies voltage to the second bit line,
a third switching element (e.g., SW5ⱼ in FIG. 4) that lowers the first bit line to ground potential,
a fourth switching element (e.g., SW6ⱼ in FIG. 4) that lowers the second bit line to ground potential,
a fifth switching element (e.g., SW1ⱼ in FIG. 4) that connects the first sense node to one (e.g., DQ in FIG. 4) of common data lines, and
a sixth switching element (e.g., SW2ⱼ in FIG. 4) that connects the second sense node to another one (e.g., /DQ in FIG. 4) of the common data lines.

In the semiconductor memory device, it is preferable that the current load circuit and the latch circuit are an identical circuit (e.g., circuit made of TR20ⱼ to TR28ⱼ in FIG. 15).

It is preferable that the semiconductor memory device further comprises:
a second sense amplifier circuit in addition to the sense amplifier circuit, the second sense amplifier circuit including
   a third sense node (e.g., SNLⱼ₊₁ in FIG. 4) isolated from a third bit line (e.g., BLLⱼ₊₁ in FIG. 4) via a seventh switching element (e.g., SW3ⱼ₊₁ in FIG. 4),
   a fourth sense node (e.g., SNRⱼ₊₁ in FIG. 4) that is located opposite the third bit line (e.g., BLLⱼ₊₁ in FIG. 4) relative to the second sense amplifier circuit (e.g., S/Aⱼ₊₁ in FIG. 4) or that is isolated from another fourth bit line (e.g., BLRⱼ₊₁ in FIG. 4) adjacent to the third bit line via an eighth switching element (e.g., SW4ⱼ₊₁ in FIG. 4),
   a current load circuit (e.g., “current load circuit” belonging to S/Aⱼ₊₁ in FIG. 4) that causes electric current to flow through the third and fourth bit lines via the third and fourth sense nodes and the seventh and eighth switching elements,
   a latch circuit (e.g., “latch circuit” belonging to S/Aⱼ₊₁ in FIG. 4) that amplifies and latches a potential difference between the third and fourth sense nodes,
   a third programming circuit (e.g., “programming circuit” connected to BLLⱼ₊₁ in FIG. 4) that applies voltage to the third bit line,
   a fourth programming circuit (e.g., “programming circuit” connected to BLRⱼ₊₁ in FIG. 4) that applies voltage to the fourth bit line,
   a ninth switching element (e.g., SW5ⱼ₊₁ in FIG. 4) that lowers the third bit line to ground potential,
   a tenth switching element (e.g., SW6ⱼ₊₁ in FIG. 4) that lowers the fourth bit line to ground potential,
   an eleventh switching element (e.g., SW1ⱼ₊₁ in FIG. 4) that connects the third sense node to one (e.g., DQ in FIG. 4) of the common data lines, and
   a twelfth switching element (e.g., SW2ⱼ₊₁ in FIG. 4) that connects the fourth sense node to another one (e.g., /DQ in FIG. 4) of the common data lines.

The first sense node of the sense amplifier circuit and the third sense node of the second sense amplifier circuit are electrically short-circuited by a thirteenth switching circuit (e.g., SW7_{j,j+1} in FIG. 4), or the second sense node of the sense amplifier circuit and the fourth sense node of the second sense amplifier circuit are electrically short-circuited by a fourteenth switching circuit (e.g., SW8_{j,j+1} in FIG. 4).

In the semiconductor memory device, it is preferable that a first dummy cell (e.g., DCLⱼ in FIG. 4) having a structure identical to a structure of each memory cell is connected to the first bit line and a first dummy word line (e.g., DWLL in FIG. 4), a second dummy cell (e.g., DCRⱼ in FIG. 4) having a structure identical to the structure of each memory cell is connected to the second bit line and a second dummy word line (e.g., DWLR in FIG. 4), a third dummy cell (e.g., DCLⱼ₊₁ in FIG. 4) having a structure identical to the structure of each memory cell is connected to the third bit line and the first dummy word line, a fourth dummy cell (e.g., DCRⱼ₊₁ in FIG. 4) having a structure identical to the structure of each memory cell is connected to the fourth bit line and the second dummy word line, a stored state in the first dummy cell and a stored state in the third dummy cell are opposite to each other, and a stored state in the second dummy cell and a stored state in the fourth dummy cell are opposite to each other.

In the semiconductor memory device, it is preferable that the semiconductor body is a first semiconductor region (e.g., 8 in FIG. 17A to FIG. 17F) of a first conductivity type that is in an electrically floating state and that extends vertically in a columnar shape from a surface of the substrate, the first gate conductor layer is connected to an upper surface of the first semiconductor region via the gate insulating film (e.g., 15 in FIG. 17A to FIG. 17F), the second gate conductor layer (e.g., 3 in FIG. 17A to FIG. 17F) is connected to a columnar section of the first semiconductor region via the gate insulating film, the first impurity region and the second impurity region are second semiconductor regions (e.g., 9 and 19 in FIG. 17A to FIG. 17F) of a second conductivity type that are in contact with an upper side surface of the first semiconductor region and that are located at opposite sides thereof in a horizontal direction, the source line serving as a first metal wiring layer (e.g., 4 in FIG. 17A to FIG. 17F) is connected to the second semiconductor region (e.g., 9 in FIG. 17A to FIG. 17F) corresponding to the first impurity region, the bit line serving as a second metal wiring layer (e.g., 2 in FIG. 17A to FIG. 17F) is connected to the second semiconductor region (e.g., 19 in FIG. 17A to FIG. 17F) corresponding to the second impurity region, the word line is connected to the first gate conductor layer, and the plate line is connected to the second gate conductor layer, is isolated for every word line, and is routed parallel to the word line.

### BRIEF DESCRIPTION OF THE DRAWINGS

FIG. 1 is an equivalent circuit diagram of a memory device using semiconductor elements (referred to as “semiconductor-based memory device” hereinafter) according to a first embodiment;

FIG. 2 illustrates a “1” write (programming) operation principle of the semiconductor-based memory device according to the first embodiment;

FIG. 3 illustrates a “0” write (erasing) operation principle of the semiconductor-based memory device according to the first embodiment;

FIG. 4 is a block diagram of sense amplifier circuits of the semiconductor-based memory device according to the first embodiment;

FIG. 5 illustrates an example of the sense amplifier circuits of the semiconductor-based memory device according to the first embodiment;

FIG. 6 is a diagram in which transistors related to a basic operation for data sensing are emphasized in the sense amplifier circuits of the semiconductor-based memory device according to the first embodiment;

FIG. 7 is a diagram in which transistors related to a basic operation for latching are emphasized in the sense amplifier circuits of the semiconductor-based memory device according to the first embodiment;

FIG. 8 is a diagram in which transistors related to a basic operation for programming are emphasized in the sense amplifier circuits of the semiconductor-based memory device according to the first embodiment;

FIG. 9 is a diagram in which transistors related to a basic operation for erasing are emphasized in the sense amplifier circuits of the semiconductor-based memory device according to the first embodiment;

FIG. 10 is a diagram in which transistors related to a basic operation for reading from each sense amplifier circuit are emphasized in the sense amplifier circuits of the semiconductor-based memory device according to the first embodiment;

FIG. 11 is a diagram in which transistors related to a basic operation for writing into each sense amplifier circuit are emphasized in the sense amplifier circuits of the semiconductor-based memory device according to the first embodiment;

FIG. 12 illustrates a reading operation of the semiconductor-based memory device according to the first embodiment;

FIG. 13 illustrates a writing operation of the semiconductor-based memory device according to the first embodiment;

FIG. 14 illustrates a refreshing operation of the semiconductor-based memory device according to the first embodiment;

FIG. 15 illustrates another example of the sense amplifier circuits of the semiconductor-based memory device according to the first embodiment;

FIG. 16 illustrates row decoders, word-line driver circuits, and plate-line driver circuits of the semiconductor-based memory device according to the first embodiment;

FIG. 17A is a plan view of the semiconductor-based memory device according to the first embodiment;

FIG. 17B is a cross-sectional view taken along line AA′ in FIG. 17A;

FIG. 17C is a cross-sectional view taken along line BB′ in FIG. 17A;

FIG. 17D is a cross-sectional view taken along line CC′ in FIG. 17A;

FIG. 17E is a cross-sectional view taken along line DD′ in FIG. 17A;

FIG. 17F is a cross-sectional view taken along line EE′ in FIG. 17A;

FIG. 18A is a plan view of a semiconductor-based memory device according to a second embodiment;

FIG. 18B is a cross-sectional view taken along line AA′ in FIG. 18A;

FIG. 18C is a cross-sectional view taken along line BB′ in FIG. 18A;

FIG. 18D is a cross-sectional view taken along line CC′ in FIG. 18A;

FIG. 18E is a cross-sectional view taken along line DD′ in FIG. 18A;

FIG. 18F is a cross-sectional view taken along line EE′ in FIG. 18Aⱼ and

FIG. 19 is an equivalent circuit diagram of the semiconductor-based memory device according to the second embodiment.

### DESCRIPTION OF THE PREFERRED EMBODIMENTS

A memory device using semiconductor elements (referred to as “semiconductor-based memory device” hereinafter) according to an embodiment of the present invention will be described below with reference to the drawings.

### First Embodiment

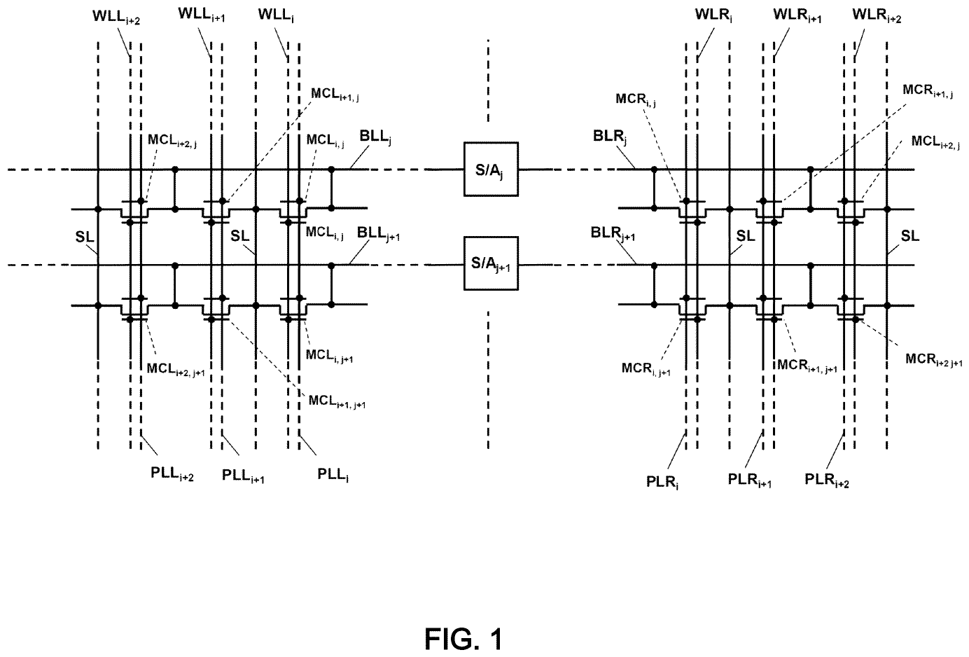

An equivalent circuit of memory cells and sense amplifier circuits of a semiconductor-based memory device according to this embodiment will now be described with reference to FIG. 1. FIG. 1 illustrates a state where a sense amplifier circuit (S/Aⱼ) is provided at the center in the row direction (i.e., a direction parallel to word lines WLLᵢ or WLRᵢ) of a cell array having multiple memory cells (MCL_{i,j}, MCL_{i+1,j}, MCL_{i+2,j}, MCL_{i,j+1}, MCL_{i+1,j+1}, MCL_{i+2,j+1}, MCR_{i,j}, MCR_{i+1,j}, MCR_{i+2,j}, MCR_{i,j+1}, MCR_{i+1,j+1}, and MCR_{i+2,j+1}) arranged in a matrix. Each of the memory cells according to this embodiment is formed of a conventionally-known n-type MOSFET whose body is in an electrically floating state (see US 2023/0077140 A1 and U.S. Pat. No. 11,823,727 B2). The source or the drain of each memory cell is connected to a bit line BLLⱼ/BLRⱼ or a source line SL. Furthermore, the floating body is connected to a plate line PLLᵢ or PLRᵢ via a capacitor. This memory cell is a type of a cell that stores data by accumulating multiple carriers into the floating body. When a state where a large number of the multiple carriers are accumulated is defined as “1” and a small number thereof are accumulated is defined as “0”, a threshold voltage of the memory cell in the “1” state is lower than that in the “0” state. When reading is performed under the same voltage condition, a larger amount of electric current flows through the “1” cell than through the “0” cell, so that data identification becomes possible.

An example of the structure of each memory cell according to this embodiment will be described in detail. The memory cell of this example has an electrically-floating semiconductor body, a first impurity region connected to a source line that is in contact with opposite ends of the semiconductor body, a second impurity region connected to a bit line, a gate insulating film that is in contact with the semiconductor body, a first gate conductor layer that is in contact with the gate insulating film and that is connected to a word line, and a second gate conductor layer that is in contact with the gate insulating film and that is connected to a plate line.

In FIG. 1, each of word lines located to the left of the sense amplifier circuit (S/Aⱼ) and each of word lines located to the right thereof will be indicated as WLLᵢ and WLRᵢ, respectively. In this case, i denotes a natural number indicating the number of a word line (1≤i≤M). Likewise, each of bit lines located to the left of the sense amplifier circuit (S/Aⱼ) and each of bit lines located to the right thereof will be indicated as BLLⱼ and BLRⱼ, respectively. In this case, j denotes a natural number indicating the number of a bit line (1≤j≤N). FIG. 1 only illustrates a total of six word lines WLLᵢ, WLLᵢ₊₁, WLLᵢ₊₂, WLRᵢ, WLRᵢ₊₁, and WLRᵢ₊₂, three at each of the left and right sides, and a total of four bit lines BLLⱼ, BLLⱼ₊₁, BLRᵢ, and BLRⱼ₊₁, two at each of left and right sides. Moreover, only a total of six plate lines PLLᵢ, PLLᵢ₊₁, PLLᵢ₊₂, PLRᵢ, PLRᵢ₊₁, and PLRᵢ₊₂, three at each of the left and right sides, are illustrated. The word lines, the source lines, and the plate lines are all routed parallel to one another, whereas the bit lines are routed in a direction perpendicular thereto. The j-th sense amplifier circuit (S/Aⱼ) is connected to the j-th bit line BLLⱼ at the left side and the j-th bit line BLRⱼ at the right side. The memory cells connected to the bit line BLLⱼ and the word lines WLLᵢ, WLLᵢ₊₁, and WLLᵢ₊₂ located at the left side will respectively be defined as MCL_{i,j}, MCL_{i+1,j}, and MCL_{i+2,j}, and the memory cells connected to the bit line BLLⱼ₊₁ and the word lines WLLᵢ, WLLᵢ₊₁, and WLLᵢ₊₂ located at the left side will respectively be defined as MCL_{i,j+1}, MCL_{i+1,j+1}, and MCL_{i+2,j+1}. Likewise, the memory cells connected to the bit line BLRⱼ and the word lines WLRᵢ, WLRᵢ₊₁, and WLRᵢ₊₂ located at the right side will respectively be defined as MCR_{i,j}, MCR_{i+1,j}, and MCR_{i+2,j}, and the memory cells connected to the bit line BLRⱼ₊₁ and the word lines WLRᵢ, WLRᵢ₊₁, and WLRᵢ₊₂ located at the right side will respectively be defined as MCR_{i,j+1}, MCR_{i+1,j+1}, and MCR_{i+2,j+1.}

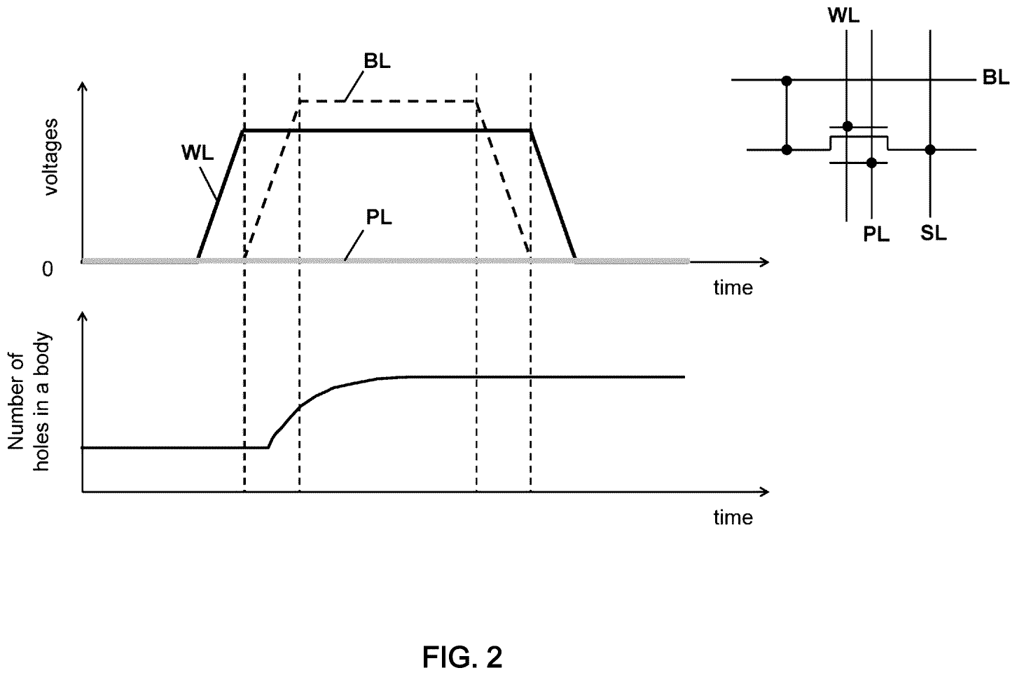

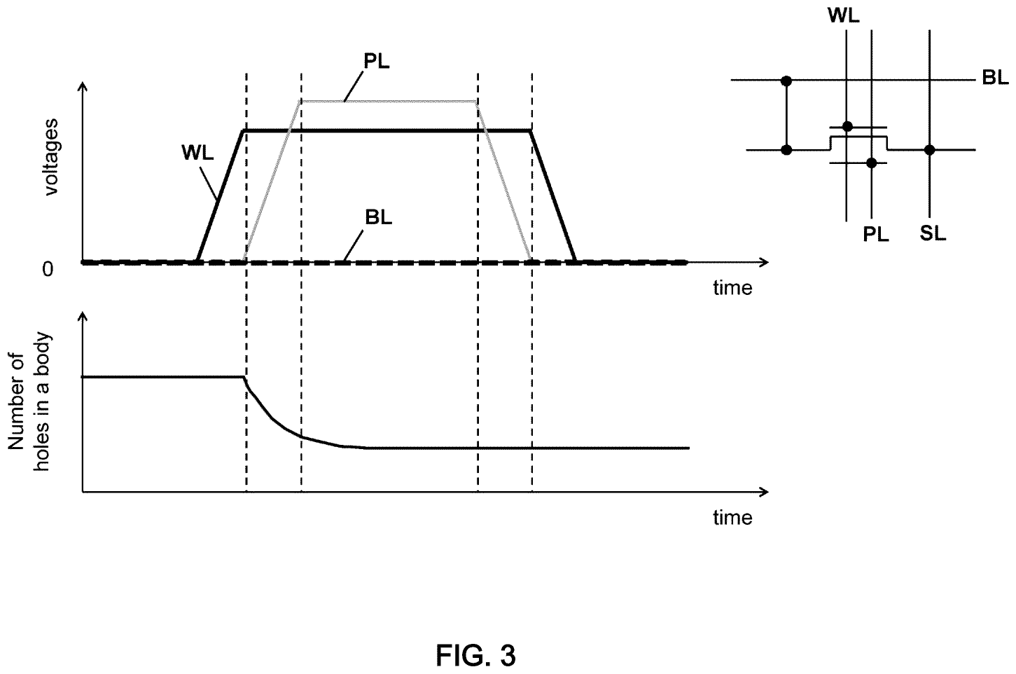

A writing operation for accumulating holes serving as the multiple carriers into the floating body of each memory cell of the semiconductor-based memory device according to this embodiment will now be described with reference to FIG. 2. When the MOSFET of the memory cell is set to a saturated state by applying positive voltage to the word line and positive voltage to the bit line, the vicinity of the drain (i.e., a node connected to the bit line) of the MOSFET enters the pinch-off state. The electrons flowing through the channel are accelerated by a high electric field and collide with silicon atoms, so that a large number of electron-hole pairs are generated (impact ionization). The electrons flow into the bit line, and the holes flow into the floating body. As a result, the holes accumulate in the floating body, so that a state where many holes are accumulated in the body is realized. This state will be defined as “1”. Similarly, an operation for extracting holes from the floating body of each memory cell of the semiconductor-based memory device according to this embodiment will be described with reference to FIG. 3. From a state where the gate (word line) and the drain (bit line) of the MOSFET of the memory cell are both set to 0 V, the plate line (PL) is raised to a positive potential. Accordingly, many holes accumulated within the floating body flow out from the floating body, which is composed of p-type silicon, to an n-type silicon layer (such as the source line or the bit line), thus resulting in a decrease in the number of holes accumulated in the floating body. This state will be defined as “0”. The method for realizing the “1” state and the method for realizing the “0” state described above are examples, and may be any of other methods.

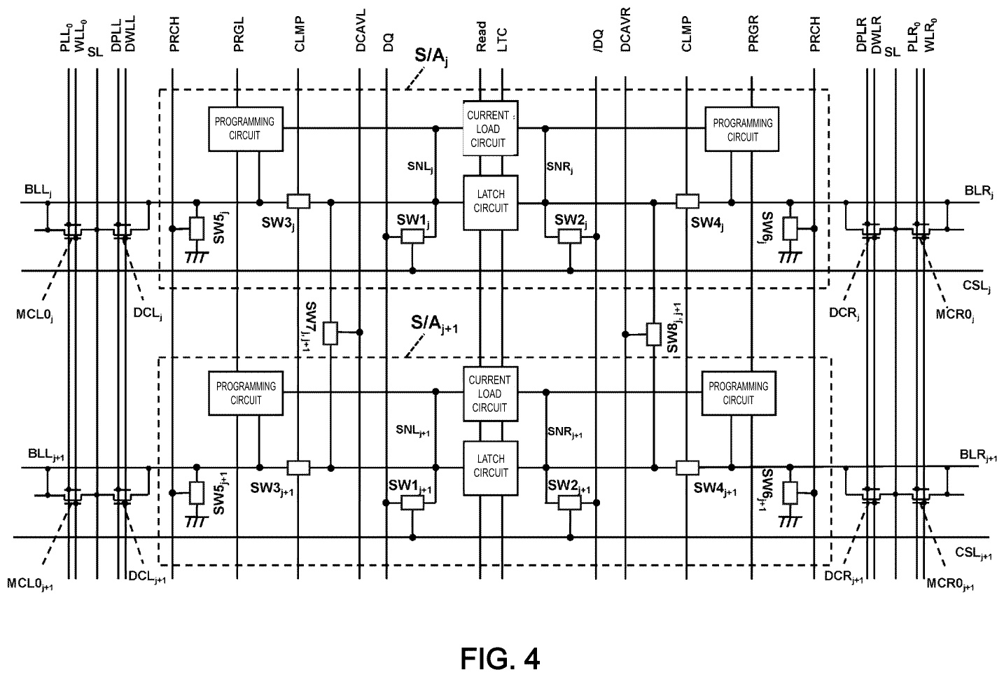

The configuration of a memory cell array and each sense amplifier circuit will now be described with reference to FIG. 4. The j-th sense amplifier circuit S/Aⱼ will be described. Provided are the sense amplifier circuit S/Aⱼ (as an example of a sense amplifier circuit according to claim 1), memory cells MCL0ⱼ, MCR0ⱼ (as an example of memory cells according to claim 1), plate lines PLL₀, PLR₀ (as an example of a plate line according to claim 1), and word lines WLL₀, WLR₀ (as an example of a word line according to claim 1). The sense amplifier circuit S/Aⱼ has a sense node pair SNLⱼ, SNRⱼ isolated from a bit line pair BLLⱼ, BLRⱼ (as an example of a bit line according to claim 1) via a first switching element pair SW3ⱼ, SW4ⱼ (as an example of a first switching circuit according to claim 1), a current load circuit that causes electric current to flow through the bit line pair BLLⱼ, BLRⱼ via the sense node pair SNLⱼ, SNRⱼ and the first switching element pair SW3ⱼ, SW4ⱼ, a latch circuit that amplifies and latches a potential difference of the sense node pair SNLⱼ, SNRⱼ, a programming circuit pair that applies voltage to the bit line pair BLLⱼ, BLRⱼ, a second switching element pair SW5ⱼ, SW6ⱼ that lowers the bit line pair BLLⱼ, BLRⱼ to ground potential, and a third switching element pair SW1ⱼ, SW2ⱼ (as an example of a second switching circuit according to claim 1) that connects the sense node pair to a common data line pair (as an example of a data line according to claim 1). Each of the memory cells MCL0ⱼ, MCR0ⱼ is constituted of a metal-oxide-semiconductor field-effect transistor whose body having a drain or source connected to the bit line pair BLLⱼ, BLRⱼ is in a floating state. The plate lines PLL₀, PLR₀ are capacitively-coupled to the floating bodies of the memory cells MCL0ⱼ, MCR0ⱼ. The word lines WLL₀, WLR₀ are connected to the gates of the memory cells MCL0ⱼ, MCR0ⱼ. The plate lines PLL₀, PLR₀ are routed in a one-to-one correspondence fashion with the respective word lines WLL₀, WLR₀. Although not illustrated in FIG. 4, M word lines exist at each of the left and right sides of the sensor amplifier circuit, and each of the left and right sides is additionally provided with one special word line at, for example, the closest location of the sense amplifier circuit. However, the locations are not limited. These word lines serve as dummy word lines DWLL, DWLR and are input to the gates of special memory cells. These special cells are called dummy cells DCLⱼ, DCLⱼ₊₁, DCRⱼ, and DCRⱼ₊₁ and have written therein the “1” state and the “0” state for every other bit line. Specifically, “1” is written in the dummy cell DCLⱼ, and “0” is written in the dummy cell DCLⱼ₊₁. Alternatively, this may be inverted. Likewise, “1” is written in the dummy cell DCRⱼ, and “0” is written in the dummy cell DCRⱼ₊₁. Alternatively, this may be inverted.

An example of the structure of each memory cell according to this embodiment will be described in detail. The memory cell of this example has an electrically-floating semiconductor body, a first impurity region connected to a source line that is in contact with opposite ends of the semiconductor body, a second impurity region connected to a bit line, a gate insulating film that is in contact with the semiconductor body, a first gate conductor layer that is in contact with the gate insulating film and that is connected to a word line, and a second gate conductor layer that is in contact with the gate insulating film and that is connected to a plate line.

The configuration of each sense amplifier circuit of the semiconductor-based memory device according to this embodiment will now be described with reference to a circuit block diagram in FIG. 4. In FIG. 4, areas surrounded by dashed lines indicate sense amplifier circuits S/Aⱼ, S/Aⱼ₊₁. Since the two have completely the same configuration, the sense amplifier circuit S/Aⱼ will be described. The central part of the sense amplifier circuit S/Aⱼ is provided with the current load circuit and the latch circuit. These circuits are controlled based on a signal Read and a signal LTC. The left sense node SNLⱼ and the right sense node SNRⱼ are shared. The left sense node SNLⱼ is connected to the left bit line BLLⱼ via the switching element SW3ⱼ, and the right sense node SNRⱼ is connected to the right bit line BLRⱼ via the switching element SW4ⱼ. The switching elements SW3ⱼ and SW4ⱼ are both controlled based on a signal CLMP. The left sense node SNLⱼ is input to the left programming circuit, and the output of the left programming circuit is connected to the left bit line BLLⱼ. The left programming circuit is controlled based on a signal PRGL. Likewise, the right sense node SNRⱼ is input to the right programming circuit, and the output of the right programming circuit is connected to the right bit line BLRⱼ. The right programming circuit is controlled based on a signal PRGR. The left sense node SNL is connected to the DQ side of a common data line pair DQ, /DQ via a switching element SW1ⱼ controlled by a j-th column select line CSLⱼ. The right sense node SNRⱼ is connected to the /DQ side of the common data line pair DQ, /DQ via a switching element SW2ⱼ controlled by the j-th column select line CSLⱼ. The left and right bit lines BLLⱼ and BLRⱼ are connected to ground (OV) via the switching elements SW5ⱼ and SW6ⱼ controlled based on a signal PRCH. The left sense node SNLⱼ of the j-th sense amplifier circuit S/Aⱼ and the left sense node SNLⱼ₊₁ of the (j+1)-th sense amplifier circuit S/Aⱼ₊₁ are short-circuited via a switching element SW7_{j,j+1} controlled based on a signal DCAVL. Likewise, the right sense node SNRⱼ of the j-th sense amplifier circuit S/Aⱼ and the right sense node SNRⱼ₊₁ of the (j+1)-th sense amplifier circuit S/Aⱼ₊₁ are short-circuited via a switching element SW8_{j,j+1} controlled based on a signal DCAVR. Although the current load circuit and the latch circuit are isolated from each other as separate circuits in FIG. 4, these circuits may be merged into a single circuit block.

A standby state of the block diagram of the memory cell array and the sense amplifier circuits illustrated in FIG. 4 will now be described. This standby state is a state prior to the start of any basic operation or a state after any basic operation is completed. First, the source lines are always connected to ground. In the standby state, the word lines and the dummy word lines are all connected to ground, and the plate lines are all set to a negative potential (VPLH). The signal CLMP is used for controlling all of the switching elements SW3ⱼ, SW3ⱼ₊₁, SW4ⱼ, and SW4ⱼ₊₁ to an ON mode (to a positive voltage V_{CLMP}). The signal PRCH is used for controlling all of the switching elements SW5ⱼ, SW5ⱼ₊₁, SW6ⱼ, and SW6ⱼ₊₁ to an ON mode and for connecting all of the bit lines BLLⱼ, BLLⱼ₊₁, BLRⱼ, and BLRⱼ₊₁ and all of the sense nodes SNLⱼ, SNLⱼ₊₁, SNRⱼ, and SNRⱼ₊₁ to ground. The column select lines CSLⱼ and CSLⱼ₊₁ are in a non-selected state, and the switching elements SW1ⱼ, SW1ⱼ₊₁, SW2ⱼ, and SW2ⱼ₊₁ are in an OFF mode. The current load circuit is set in a state where it does not draw load current in accordance with the signal Read, and the latch circuit is set in a deactivated state in accordance with the signal LTC. The left and right programming circuits are set in a state where they do not release output to the left and right bit lines in accordance with the signals PRGL and PRGR. The signals DCAVL and DCAVR are used for controlling the switching elements SW7_{j,j+1} and SW8_{j,j+1} to an OFF mode. The above state is the standby state.

The basic operation of the memory cells and the sense amplifier circuits of the semiconductor-based memory device according to this embodiment will now be described with reference to FIG. 4.

First, a basic operation for “data sensing” in the memory cells and the sense amplifier circuits of the semiconductor-based memory device according to this embodiment will be described. The following is an assumed case where data stored in the cells MCL0ⱼ and MCL0ⱼ₊₁ located to the left of the sense amplifier circuits (assuming that “0” data is stored in the cell MCL0ⱼ and “1” data is stored in the cell MCL0ⱼ₊₁) are sensed by the corresponding sense amplifier circuits S/Aⱼ and S/Aⱼ₊₁. The operation commences from the standby state. First, a grounding operation of all of the bit lines is stopped based on the signal PRCH, and the bit lines are set to a floating 0 V state. Then, a word line WLL₀ selected based on an address within the left cell array is raised from a ground level to a read positive voltage V_{WLR}. At the same time, the dummy word line DWLR within the right cell array is raised from the ground level to the read positive voltage V_{WLR}. Subsequently, the current load circuits are activated based on the signal Read, and electric current is caused to flow from a power-supply voltage V_{dd} to the memory cells MCL0ⱼ and MCL0ⱼ₊₁ and the dummy cells DCRⱼ and DCRⱼ₊₁ via the bit lines. This electric current is to be drawn to the source lines SL at the ground level via the memory cells and the dummy cells. In this case, the right sense nodes SNRⱼ and SNRⱼ₊₁ are electrically short-circuited by the switching element SW8_{j,j+1} (by activating the signal DCAVR). Since the dummy cells DCRⱼ and DCRⱼ₊₁ have mutually opposite data pre-written therein, this electrical short circuit causes a reference current I_{ref}, which is an average of the read current of the cell having “1” stored therein and the read current of the cell having “0” stored therein, to flow through the right bit lines BLRⱼ and BLRⱼ₊₁ (I_{ref}=1/2 (I₀ and I₁), where I₀ denotes the read current of the “0” cell and In denotes the read current of the “1” cell). On the other hand, based on the above assumption, I₀ and I₁ respectively flow through the left bit lines BLLⱼ and BLLⱼ₊₁. In such a situation, signal development occurs such that the sense node SNLⱼ of the sense node pair SNLⱼ, SNRⱼ of the sense amplifier circuit S/Aⱼ increases in voltage quicker toward the power-supply voltage V_{dd} than the sense node SNLR. With regard to the sense node pair SNLⱼ₊₁, SNRⱼ₊₁ of the sense amplifier circuit S/Aⱼ₊₁, signal development occurs such that the sense node SNRⱼ₊₁ increases in voltage quicker toward the power-supply voltage V_{dd} than the sense node SNLⱼ₊₁. The above operation is the basic operation for “data sensing” in the memory cells and the sense amplifier circuits of the semiconductor-based memory device according to this embodiment.

Next, a basic operation for “latching” in the memory cells and the sense amplifier circuits of the semiconductor-based memory device according to this embodiment will be described. The basic operation for “latching” commences from when the basic operation for “data sensing” is completed. When a voltage difference between the sense node pairs of these sense amplifier circuits develops to a certain value or more, the signal CLMP is lowered from the voltage V_{CLMP} to the ground level, so that the sense node pairs of the sense amplifier circuits are disconnected from the bit lines. Then, by activating the signal LTC, the sense node pairs are amplified and latched to the ground level and the power-supply voltage V_{dd} level. In the above assumption, the sense node SNLⱼ is latched to the power-supply voltage V_{dd} level, and the sense node SNRⱼ is latched to the ground level. Moreover, the sense node SNLⱼ₊₁ is latched to the ground level, and the sense node SNRⱼ₊₁ is latched to the power-supply voltage V_{dd} level. The above operation is the basic operation for “latching” in the memory cells and the sense amplifier circuits of the semiconductor-based memory device according to this embodiment.

Next, a basic operation for “erasing” in the memory cells and the sense amplifier circuits of the semiconductor-based memory device according to this embodiment will be described. The basic operation for “erasing” involves setting the memory state of all of the memory cells selected on a word line to “0”. Specifically, this basic operation involves removing the holes of the multiple carriers from the floating body of each memory cell to reduce the number of holes existing therein. The basic operation for “erasing” commences from when the basic operation for “latching” is completed or from the standby state. If the basic operation for “erasing” commences from the standby state, the sense node pairs of the sense amplifier circuits are disconnected from the bit lines by lowering the signal CLMP from the V_{CLMP} level to the ground level. If the basic operation for “erasing” commences after the basic operation for “latching”, the signal CLMP is already lowered to the ground level. At the same time, if the previous cycle is the basic operation for “data sensing”, the signal PRCH is returned to the power-supply voltage V_{dd}, and the bit lines are connected to ground. Moreover, if the previous cycle is the basic operation for “data sensing”, the selected word line is returned to the ground level. Alternatively, without being returned to the ground level, the voltage may be maintained at the read positive voltage V_{WLR} or may be set to a programming positive voltage V_{WLW}. From this state, the plate line PLL₀ corresponding to the selected word line WLL₀ is set from VPLH to a positive potential V_{PLE}. Accordingly, as described in FIG. 3, the holes are removed from the floating bodies of the selected memory cells, so that the memory state of these cells is set to “0”. The above operation is the basic operation for “erasing” in the memory cells and the sense amplifier circuits of the semiconductor-based memory device according to this embodiment.

Next, a basic operation for “programming” in the memory cells and the sense amplifier circuits of the semiconductor-based memory device according to this embodiment will be described. The basic operation for “programming” involves setting the memory state to “1” for memory cells designated by the sense amplifier circuits among all memory cells in the “0” memory state selected on a word line. Specifically, this basic operation involves injecting holes of the multiple carriers into the floating body of each memory cell to increase the number of holes existing therein. The basic operation for “programming” commences from when the basic operation for “latching” is completed and when the basic operation for “erasing” is completed. First, the bit lines connected to ground are set to the floating 0 V state (i.e., the signal PRCH is lowered to the ground level). At the same time, the word line is set to the programming positive voltage V_{WLW}. Then, the programming signal PRGL at the side of the cell array to which the selected word line belongs, that is, the left side in the current case, is activated so that the bit lines are set to a programming positive voltage V_{BLW} via the programming circuits. However, these programming circuits have received the latched voltages SNLⱼ, SNLⱼ₊₁, SNRⱼ, and SNRⱼ₊₁ of the sense node pairs of the sense amplifier circuits, and the basic operation for “programming” is performed more selectively based on these voltages. The above operation is the basic operation for “programming” in the memory cells and the sense amplifier circuits of the semiconductor-based memory device according to this embodiment.

Next, a basic operation for “reading from each sense amplifier circuit” in the memory cells and the sense amplifier circuits of the semiconductor-based memory device according to this embodiment will be described. The basic operation for “reading from each sense amplifier circuit” commences from a state where the basic operation for “latching” is completed. The column select line CSLⱼ selected based on an address is raised from the ground level to the power-supply voltage V_{dd} level. Accordingly, the switching elements SW1ⱼ and SW2ⱼ are turned on, and the sense node pair SNLⱼ, SNRⱼ of the selected sense amplifier circuit S/Aⱼ are respectively connected to the common data line pair DQ, /DQ. Consequently, latched information of the sense node pair SNLⱼ and SNR of the selected sense amplifier circuit S/Aⱼ is transmitted to the common data line pair DQ and/DQ and is read by an external circuit. The above operation is the basic operation for “reading from each sense amplifier circuit” in the memory cells and the sense amplifier circuits of the semiconductor-based memory device according to this embodiment.

Next, a basic operation for “writing into each sense amplifier circuit” in the memory cells and the sense amplifier circuits of the semiconductor-based memory device according to this embodiment will be described. The basic operation for “writing into each sense amplifier circuit” commences from a state where the basic operation for “latching” is completed. The column select line CSLⱼ selected based on an address is raised from the ground level to the power-supply voltage V_{dd} level. Accordingly, the switching elements SW1ⱼ and SW2ⱼ are turned on, and the sense node pair SNLⱼ, SNRⱼ of the selected sense amplifier circuit S/Aⱼ are respectively connected to the common data line pair DQ, /DQ. At the same time, an external write circuit not illustrated in FIG. 4 inputs write data to the common data line pair DQ, /DQ. If the polarity of this data is opposite to the polarity originally latched in the sense node pair SNLⱼ, SNRⱼ of the sense amplifier circuit S/Aⱼ, the polarities of the sense nodes are inverted. Accordingly, the write data from the external circuit can be reflected on the data in the sense amplifier circuit S/Aⱼ selected on the column select line CSLⱼ. The above operation is the basic operation for “writing into each sense amplifier circuit” in the memory cells and the sense amplifier circuits of the semiconductor-based memory device according to this embodiment.

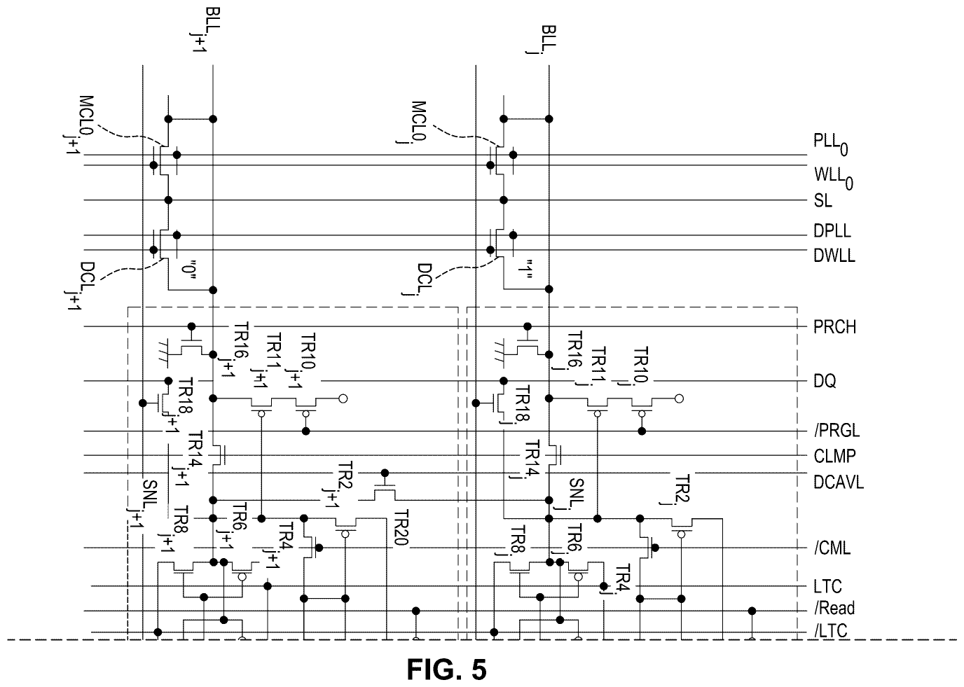

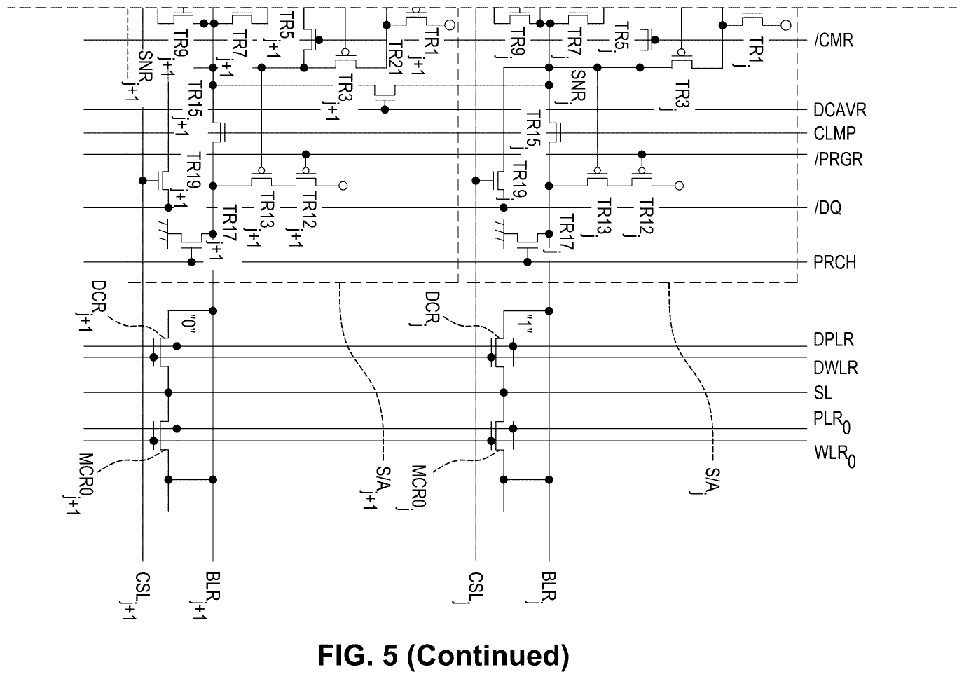

A more specific circuit configuration of the memory cells and the sense amplifier circuits of the semiconductor-based memory device according to this embodiment will now be described with reference to FIG. 5. In FIG. 5, the sense amplifier circuit S/Aⱼ includes 19 MOSFETS TRⱼ to TR19ⱼ, and the sense amplifier circuit S/Aⱼ₊₁ includes 19 MOSFETS TR1ⱼ₊₁ to TR19ⱼ₊₁. In addition to these MOSFETs, a MOSFET TR20 for electrically short-circuiting the left sense node SNLⱼ of the sense amplifier circuit S/Aⱼ and the left sense node SNLⱼ₊₁ of the sense amplifier circuit S/Aⱼ₊₁ to each other and a MOSFET TR21 for electrically short-circuiting the right sense node SNRⱼ of the sense amplifier circuit S/Aⱼ and the right sense node SNRⱼ₊₁ of the sense amplifier circuit S/Aⱼ₊₁ to each other exist. In FIG. 5, the MOSFETS TR1ⱼ to TR5ⱼ correspond to the current load circuit of the sense amplifier circuit S/Aⱼ in FIG. 4, and the MOSFETS TR1ⱼ₊₁ to TR5ⱼ₊₁ correspond to the current load circuit of the sense amplifier circuit S/Aⱼ₊₁ in FIG. 4. Furthermore, in FIG. 5, the n-type MOSFETs TR6ⱼ to TR9ⱼ correspond to the latch circuit of the sense amplifier circuit S/Aⱼ in FIG. 4, and the n-type MOSFETS TR6ⱼ₊₁ to TR9ⱼ₊₁ correspond to the latch circuit of the sense amplifier circuit S/Aⱼ₊₁ in FIG. 4. Moreover, in FIG. 5, the n-type MOSFETS TR10ⱼ to TR13; correspond to the programming circuit of the sense amplifier circuit S/Aⱼ in FIG. 4, and the n-type MOSFETS TR10ⱼ₊₁ to TR13ⱼ₊₁ correspond to the programming circuit of the sense amplifier circuit S/Aⱼ₊₁ in FIG. 4. In FIG. 5, the n-type MOSFETs TR14ⱼ to TR19ⱼ respectively correspond to the switching elements SW3ⱼ, SW4ⱼ, SW5ⱼ, SW6ⱼ, SW1ⱼ, and SW2ⱼ of the sense amplifier circuit S/Aⱼ in FIG. 4, and the n-type MOSFETS TR14ⱼ₊₁ to TR19ⱼ₊₁ respectively correspond to the switching elements SW3ⱼ₊₁, SW4ⱼ₊₁, SW5ⱼ₊₁, SW6ⱼ₊₁, SW1ⱼ₊₁, and SW2ⱼ₊₁ of the sense amplifier circuit S/Aⱼ₊₁ in FIG. 4. The n-type MOSFETS TR20 and TR21 in FIG. 5 respectively correspond to the switching elements SW7_{j,j+1} and SW8_{j,j+1} in FIG. 4. Furthermore, the signal Read for causing load current to flow through the memory cells and the dummy cells in FIG. 4 is changed to a signal/Read in FIG. 5 to indicate that it is a signal for controlling the gate of a p-type MOSFET and is to be activated when lowered to a low level. The same change is also applied to the signals PRGL and PRGR. The signal LTC for controlling each latch circuit in FIG. 4 is split into two signals in FIG. 5, namely, a signal LTC for p-type cross-coupled MOSFETs and a signal/LTC for n-type cross-coupled MOSFETs. Although each current load circuit is configured as a current mirror connection circuit using p-type MOSFETs, the current mirror connection has to be inverted depending on whether a dummy cell is connected to either a left or right sense node. Thus, the circuit configuration can be changed based on signals/CML and/CMR.

The basic operation of the memory cells and the sense amplifier circuits of the semiconductor-based memory device according to this embodiment will be described with reference to a more specific circuit by using FIG. 5 to FIG. 11.

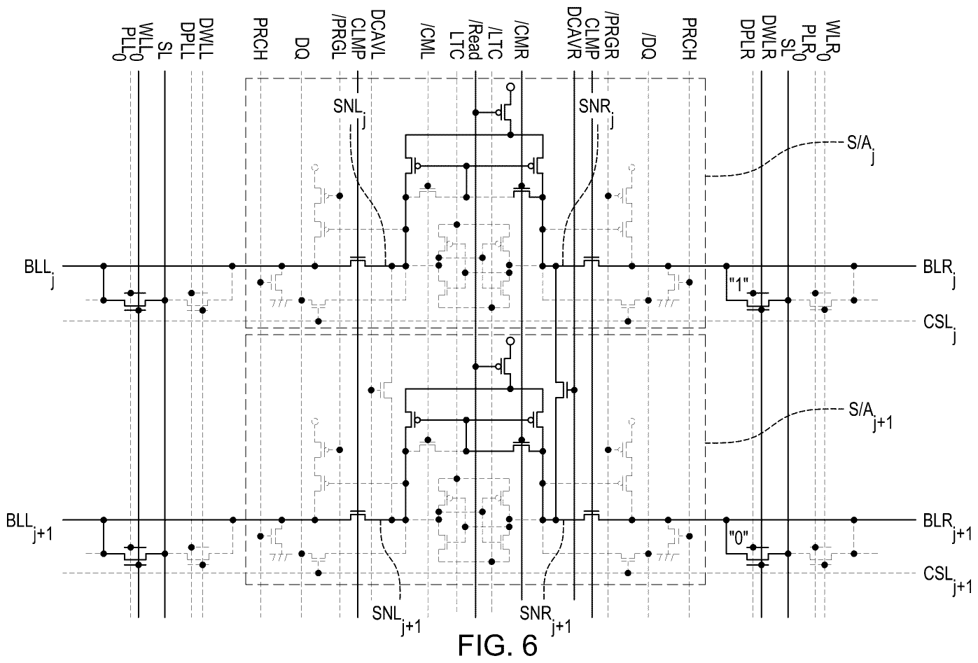

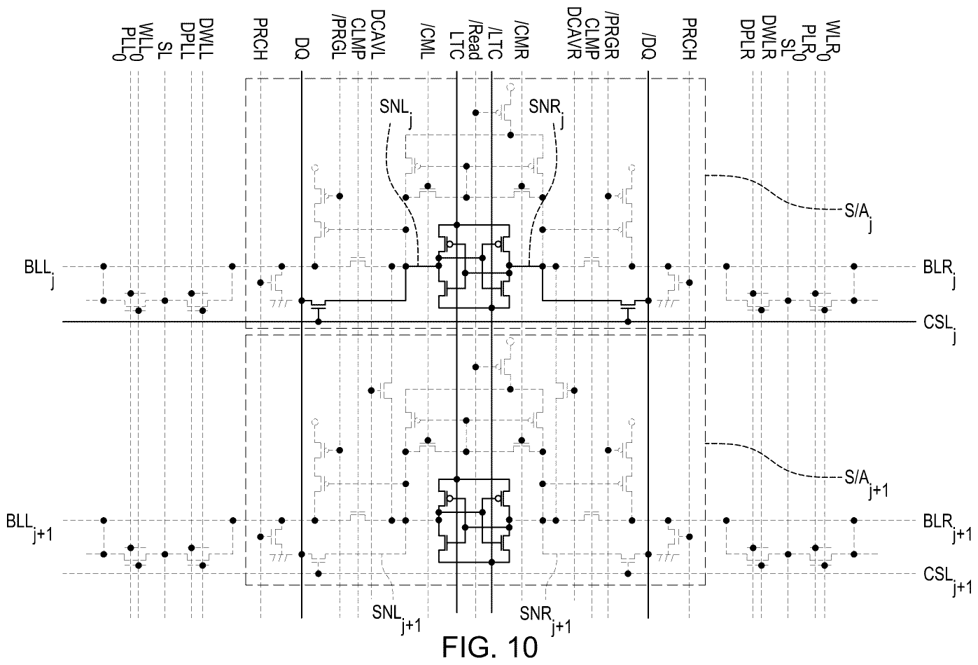

The basic operation for “data sensing” in the memory cells and the sense amplifier circuits of the semiconductor-based memory device according to this embodiment will be described with reference to FIG. 5 and FIG. 6. Of the MOSFETs illustrated in FIG. 5, MOSFETs indicated in black in FIG. 6 operate in relation to the basic operation for “data sensing”. The state prior to the start of the operation is the standby state. In the standby state, /Read, PRCH, /LTC, /PRGL, /PRGR, DQ, and/DQ are all at the power-supply voltage V_{dd} level, SNLⱼ, SNRⱼ, SNLⱼ₊₁, SNRⱼ₊₁, BLLⱼ, BLRⱼ, BLLⱼ₊₁, BLRⱼ₊₁, /CML, /CMR, CSLⱼ, CSLⱼ₊₁, DCAVL, DCAVR, WLL₀, WLR₀, DWLL, and DWLR are all at the ground level, PLL₀, PLR₀, DPLL, and DPLR are all at a negative fixed voltage VPLH level, and CLMP is at a positive fixed voltage V_{CLMP} level. SL is constantly set to the ground level. The basic operation for data sensing will be described based on FIG. 5. First, the selected word line WLL₀ is raised from the ground level to the positive voltage V_{WLR}. It is assumed here that a word line within a cell array located to the left of the sense amplifier circuits is selected. Accordingly, in the range of FIG. 4, two memory cells CLⱼ and CLⱼ₊₁ are selected (although not illustrated in FIG. 10, in actuality, all cells connected to the word line are selected). At the same time, the dummy word line DWLR located to the right of the sense amplifier circuits is similarly raised from the ground level to the positive voltage V_{WLR}. Accordingly, in the range of FIG. 5, two dummy cells DCRⱼ and DCRⱼ₊₁ are selected (although not illustrated in FIG. 10, in actuality, all dummy cells connected to the word line are selected). However, unlike the memory cells, the “1” or “0” state is preliminarily written in the dummy cells. In this embodiment, it is assumed that “1” is written in the dummy cell DCRⱼ connected to the j-th bit line BLRⱼ, and “0” is written in the dummy cell DCRⱼ₊₁ connected to the (j+1)-th bit line BLRⱼ₊₁. In other words, opposite data is written in every other dummy cell. The polarities of “1” and “0” may be opposite to each other. After the dummy cells are selected, the signal DCAVR rises from the ground level to the power-supply voltage V_{dd} level. Accordingly, the right sense nodes SNRⱼ and SNRⱼ₊₁ corresponding to two adjacent bit lines are electrically short-circuited by the MOSFET TR21. Consequently, an intermediate current of the electric currents caused to flow by the cells in the “1” state and the “0” state flows through the right sense nodes SNRⱼ and SNRⱼ₊₁. At the same time, as illustrated in FIG. 5, the signal/CML rises from the ground level to the power-supply voltage V_{dd} level. Accordingly, the MOSFETs TR5ⱼ and TR5ⱼ₊₁ continue to be in the ON mode, whereas the MOSFETS TR4ⱼ and TR4ⱼ₊₁ are switched to the OFF mode, so that the current mirror circuit causes the reference current to be input toward the right sense nodes SNRⱼ and SNRⱼ₊₁. Then, the signal/Read is lowered from the power-supply voltage V_{dd} level to the ground level, so that the current mirror circuit is supplied with electric current from the power-supply voltage V_{dd}, whereby voltage signals develop between the sense node pair SNRⱼ and SNLⱼ and between the sense node pair SNRⱼ₊₁ and SNLⱼ₊₁. The above operation is the basic operation for “data sensing” in the memory cells and the sense amplifier circuits of the semiconductor-based memory device according to this embodiment.

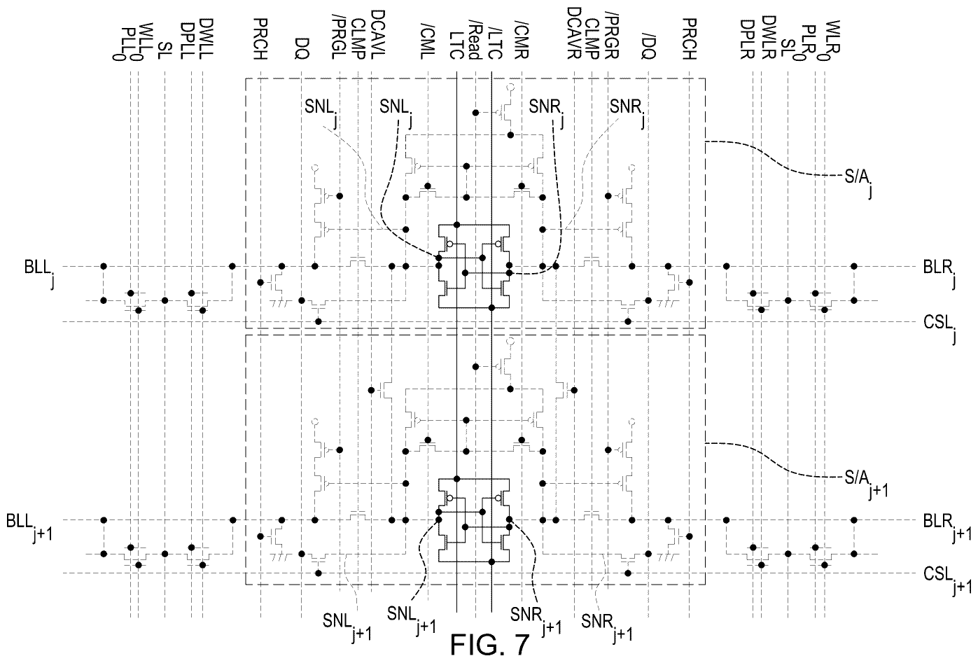

The basic operation for “latching” in the memory cells and the sense amplifier circuits of the semiconductor-based memory device according to this embodiment will be described with reference to FIG. 5 and FIG. 7. Of the MOSFETs illustrated in FIG. 5, MOSFETs indicated in black in FIG. 7 operate in relation to the basic operation for “latching”. The state prior to the start of the operation is a state where the basic operation for “data sensing” is completed. Specifically, this is a state where the voltage signals develop between the sense node pair SNRⱼ and SNL and between the sense node pair SNRⱼ₊₁ and SNLⱼ₊₁. Whether to wait for the start of the basic operation for “latching” until how much these voltage signals develop depends on the degree of manufacturing variations in the threshold voltages for the MOSFETS TR6ⱼ, TR7ⱼ, TR8ⱼ, and TR9ⱼ and the MOSFETS TR6ⱼ₊₁, TR7ⱼ₊₁, TR8ⱼ₊₁, and TR9ⱼ₊₁, indicated in black in FIG. 7, constituting the latch circuits. Normally, the basic operation for “latching” has to commence after voltage signals large enough for the latch circuits to properly perform the basic operation for “latching” develop between the sense node pair SNRⱼ and SNLⱼ and between the sense node pair SNRⱼ₊₁ and SNLⱼ₊₁. At this timing, the signal LTC rises from the ground level to the power-supply voltage V_{dd} level, and the signal/LTC falls from the power-supply voltage V_{dd} level to the ground level, so that the signals developed in the basic operation for “data sensing” between the sense node pair SNRⱼ and SNL and between the sense node pair SNRⱼ₊₁ and SNLⱼ₊₁ are amplified and latched to signals between the ground level and the power-supply voltage V_{dd} level. The above operation is the basic operation for “latching” in the memory cells and the sense amplifier circuits of the semiconductor-based memory device according to this embodiment.

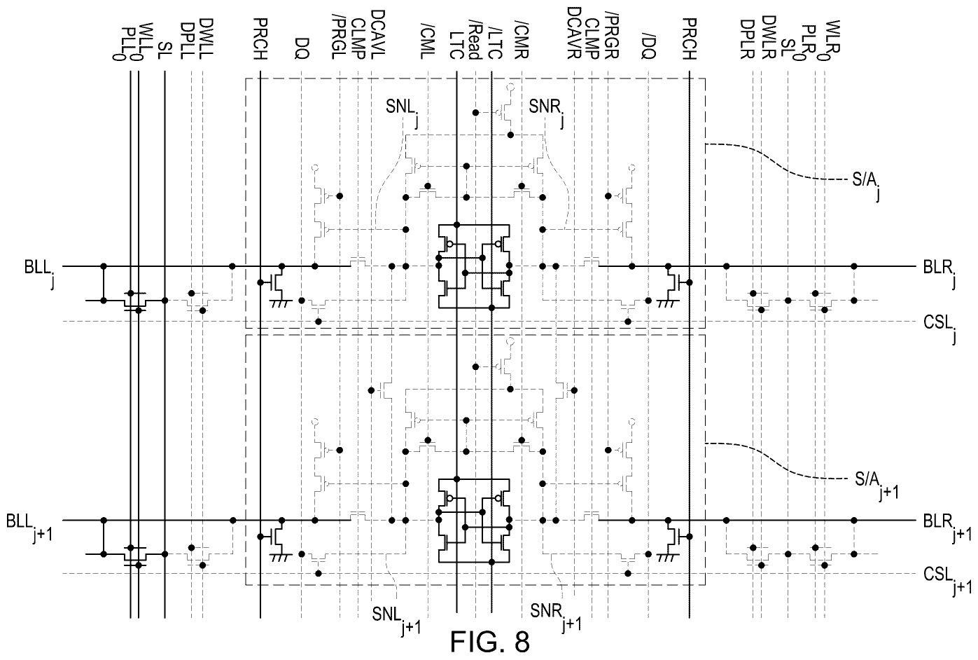

The basic operation for “erasing” in the memory cells and the sense amplifier circuits of the semiconductor-based memory device according to this embodiment will be described with reference to FIG. 5 and FIG. 8. Of the MOSFETs illustrated in FIG. 5, MOSFETs indicated in black in FIG. 8 operate in relation to the basic operation for “erasing”. The state prior to the start of the operation is a state where the basic operation for “latching” is completed or is the standby state. In the basic operation for “erasing”, the bit lines have to be isolated from the sense amplifier circuits. Therefore, the signal CLMP has to be lowered from the voltage V_{CLMP} to the ground level. Moreover, the bit lines have to be set to the ground level, and the signal PRCH has to be raised to the power-supply voltage V_{dd} level. As illustrated in FIG. 8, by raising the plate line PLL₀ from the negative potential VPLH to the positive potential V_{PLE} in a state where the word line is lowered to the ground level, holes can be extracted from the floating bodies of the cells CL0ⱼ and CL0ⱼ₊₁. Although the description of this embodiment only refers to two cells MCL0ⱼ and MCL0ⱼ₊₁ within a cell array located to the left of the sense amplifier circuits, it is possible in actuality to simultaneously extract holes from the floating bodies of all of the memory cells along a single word line within the cell array located to the left of the sense amplifier circuits. The above operation is the basic operation for “erasing” in the memory cells and the sense amplifier circuits of the semiconductor-based memory device according to this embodiment. It is assumed that, during the basic operation for “erasing”, the word line WLL₀ is activated to high voltage.

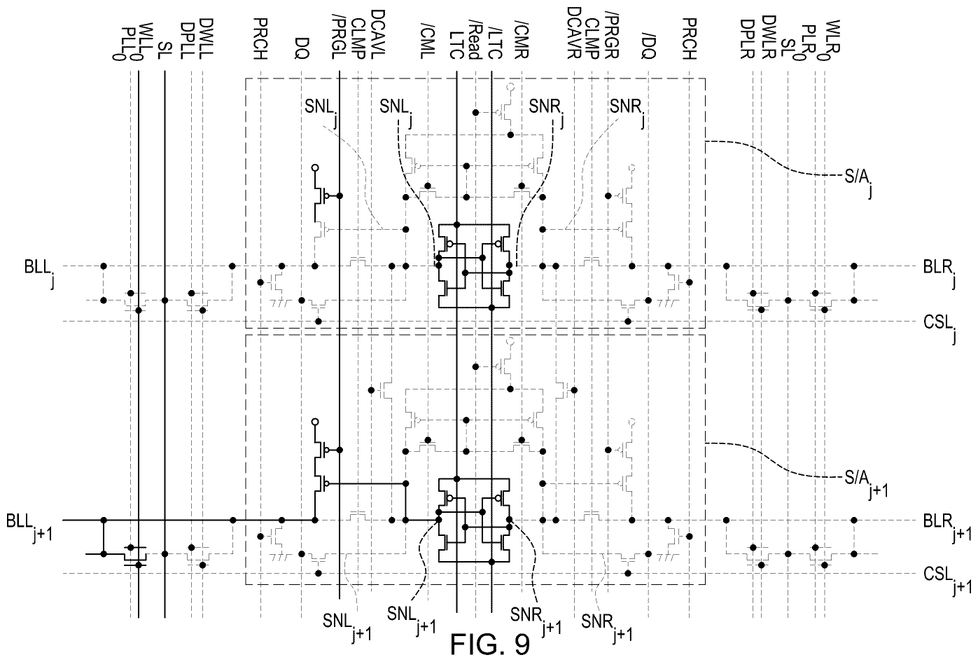

The basic operation for “programming” in the memory cells and the sense amplifier circuits of the semiconductor-based memory device according to this embodiment will be described with reference to FIG. 5 and FIG. 9. Of the MOSFETs illustrated in FIG. 5, MOSFETs indicated in black in FIG. 9 operate in relation to the basic operation for “programming”. The state prior to the start of the operation is a state where the basic operation for “latching” is completed, that is, a state where the voltage signals at the power-supply voltage V_{dd} level and the ground level are latched between the sense node pair SNRⱼ and SNLⱼ as well as between the sense node pair SNRⱼ₊₁ and SNLⱼ₊₁, and a time point when the basic operation for “erasing” is completed. In this description, it is assumed that the sense node SNRⱼ is at the ground level and the sense node SNLⱼ is at the power-supply voltage V_{dd} level. Likewise, it is assumed that the sense node SNRin is at the power-supply voltage V_{dd} level and the sense node SNLⱼ₊₁ is at the ground level. The basic operation for “programming” commences by raising the word line WLL₀ connected to the memory cells performing the programming to the value of V_{WLW} at the word line level during the programming. The basic operation for “latching” has to continue during the duration of this basic operation for programming. In such a condition, the programming signal/PRGL at the side of the cell array (i.e., the cell array located to the left of the sense amplifier circuits in this description) where the word line is selected is lowered from the power-supply voltage V_{dd} level to the ground level. Accordingly, the p-type MOSFETs TR10ⱼ and TR10ⱼ₊₁ are turned on. On the other hand, based on the above assumption, SNLⱼ is at the power-supply voltage V_{dd} level and SNLⱼ₊₁ is at the ground level, so that the MOSFET TR11ⱼ is in an OFF mode and the MOSFET TR11ⱼ₊₁ is in an ON mode. Therefore, the bit line BLLⱼ remains to be at the ground level by the memory cell MCL0ⱼ, whereas the bit line BLLⱼ₊₁ is raised to the power-supply voltage V_{dd}. Consequently, although electric current does not flow through the memory cell MCL0ⱼ, the memory cell MCL0ⱼ₊₁ is biased toward a saturated state so that impact ionization occurs, whereby holes accumulate in the floating body thereof. Thus, programming can be executed on the memory cell MCL0ⱼ₊₁. Accordingly, whether or not programming is to be executed depends on the latch state of each sense amplifier circuit. The above operation is the basic operation for “programming” in the memory cells and the sense amplifier circuits of the semiconductor-based memory device according to this embodiment. There are other conceivable methods for programming, and the above-described method is an example.

The basic operation for “reading from each sense amplifier circuit” in the memory cells and the sense amplifier circuits of the semiconductor-based memory device according to this embodiment will be described with reference to FIG. 5 and FIG. 10. Of the MOSFETs illustrated in FIG. 5, MOSFETs indicated in black in FIG. 10 operate in relation to the basic operation for “reading from each sense amplifier circuit”. The state prior to the start of the operation is a state where the basic operation for “latching” is completed. Specifically, this is a state where the voltage signals at the power-supply voltage V_{dd} level and the ground level are latched between the sense node pair SNRⱼ and SNLⱼ and between the sense node pair SNRⱼ₊₁ and SNLⱼ₊₁. In this description, it is assumed that the sense node SNRⱼ is at the ground level and the sense node SNLⱼ is at the power-supply voltage V_{dd} level. Likewise, it is assumed that the sense node SNRⱼ₊₁ is at the power-supply voltage V_{dd} level and the sense node SNLⱼ is at the ground level. In the basic operation for “reading from each sense amplifier circuit”, the sense amplifier circuits have to be isolated from the bit lines. Therefore, the signal CLMP has to be lowered from the voltage V_{CLMP} to the ground level. The selected column select line CSLⱼ rises from the ground level to the power-supply voltage V_{dd} level, and the common data line pair DQ, /DQ pre-charged to the power-supply voltage V_{dd} level and the sense node pair SNLⱼ, SNR of the selected sense amplifier S/Aⱼ are electrically short-circuited by turning on the MOSFETs TR18ⱼ and TR19ⱼ. Accordingly, DQ is maintained at the power-supply voltage V_{dd} level, whereas/DQ is lowered from the power-supply voltage V_{dd} level to a lower voltage by the MOSFET TR9ⱼ. Thus, a voltage difference occurs between the common data line pair DQ, /DQ. By amplifying this using an external circuit, such as a secondary sense amplifier circuit not illustrated in FIG. 4 and FIG. 9, data stored in the memory cell MCL0ⱼ can be read by an external unit. The above operation is the basic operation for “reading from each sense amplifier circuit” in the memory cells and the sense amplifier circuits of the semiconductor-based memory device according to this embodiment.

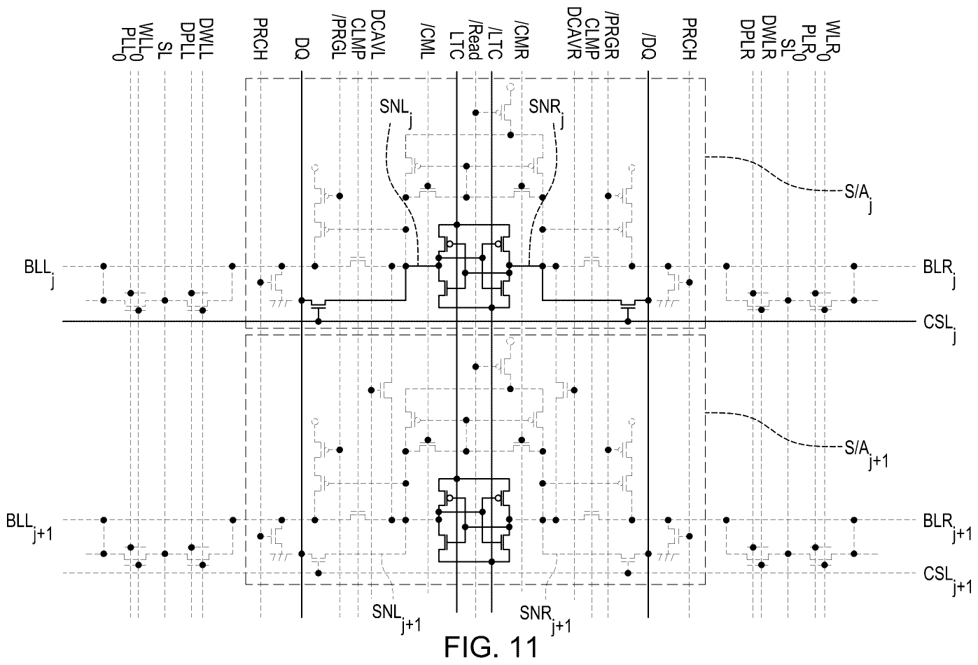

The basic operation for “writing into each sense amplifier circuit” in the memory cells and the sense amplifier circuits of the semiconductor-based memory device according to this embodiment will be described with reference to FIG. 5 and FIG. 11. Of the MOSFETs illustrated in FIG. 5, MOSFETs indicated in black in FIG. 11 operate in relation to the basic operation for “writing into each sense amplifier circuit”. The state prior to the start of the operation is a state where the basic operation for “latching” is completed. Specifically, this is a state where the voltage signals at the power-supply voltage V_{dd} level and the ground level are latched between the sense node pair SNRⱼ and SNLⱼ as well as between the sense node pair SNRⱼ₊₁ and SNLⱼ₊₁. In this description, it is assumed that the sense node SNRⱼ is at the ground level and the sense node SNLⱼ is at the power-supply voltage V_{dd} level. Likewise, it is assumed that the sense node SNRin is at the power-supply voltage V_{dd} level and the sense node SNLⱼ₊₁ is at the ground level. In the basic operation for “writing into each sense amplifier circuit”, the sense amplifier circuits have to be isolated from the bit lines. Therefore, the signal CLMP has to be lowered from the voltage V_{CLMP} to the ground level. The selected column select line CSLⱼ rises from the ground level to the power-supply voltage V_{dd} level, and the common data line pair DQ, /DQ and the selected sense node pair SNLⱼ, SNRⱼ of the sense amplifier circuit S/Aⱼ are electrically short-circuited by turning on the MOSFETs TR18ⱼ and TR19ⱼ. In this state, assuming that DQ is driven to the ground level and/DQ is driven to the power-supply voltage V_{dd} level from a write circuit not illustrated in FIG. 4 or FIG. 10, the latch circuit (TR6ⱼ, TR7ⱼ, TR8ⱼ, TR9ⱼ) within the sense amplifier circuit S/Aⱼ is inverted from a state where the sense nodes SNRⱼ and SNLⱼ are respectively latched to the ground level and the power-supply voltage V_{dd} level to an opposite state where the sense nodes SNR and SNLⱼ are respectively latched to the power-supply voltage V_{dd} level and the ground level. Accordingly, the basic operation for “writing into each sense amplifier circuit” is executed. The above operation is the basic operation for “writing into each sense amplifier circuit” in the memory cells and the sense amplifier circuits of the semiconductor-based memory device according to this embodiment.

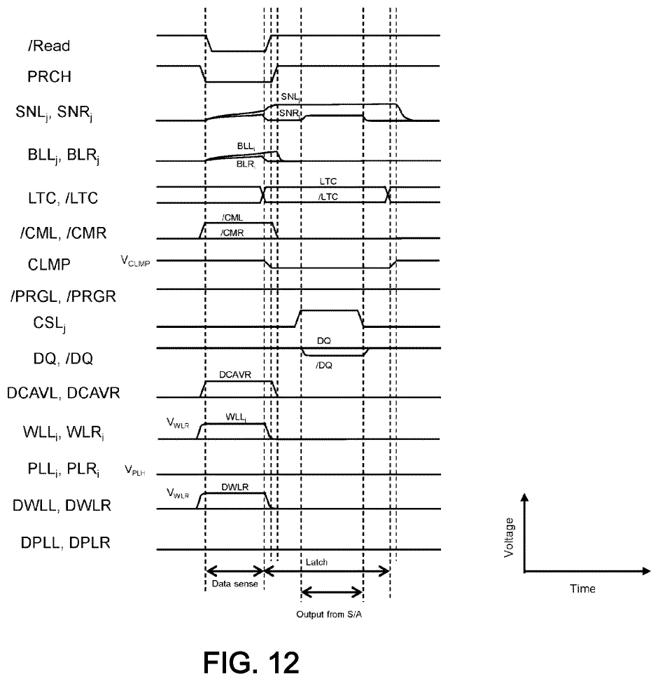

A reading operation of the semiconductor-based memory device according to this embodiment will now be described with reference to FIG. 12. This can be implemented by combining some of the basic operations of each sense amplifier circuit of the semiconductor-based memory device according to this embodiment. The reading operation of the semiconductor-based memory device according to this embodiment includes three basic operations, namely, “data sensing”, “latching”, and “reading from each sense amplifier circuit”, of the sense amplifier circuit of the semiconductor-based memory device according to this embodiment. First, a transition is made from the standby state to the basic operation for “data sensing”. Then, the basic operation for “latching” commences. In a state where data is being latched, data of the sense amplifier circuit S/Aⱼ selected on the column select line CSLⱼ in the data is read to an external unit via the common data line pair DQ, /DQ. In other words, the data is read to the external unit by “reading from each sense amplifier circuit”.

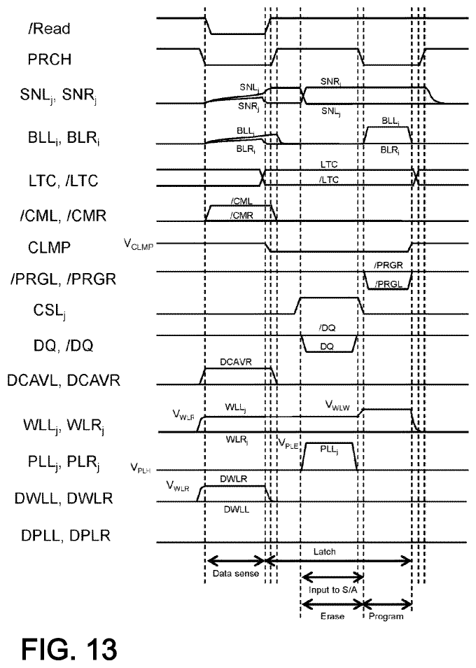

A writing operation of the semiconductor-based memory device according to this embodiment will now be described with reference to FIG. 13. This can be implemented by combining some of the basic operations of each sense amplifier circuit of the semiconductor-based memory device according to this embodiment. The writing operation of the semiconductor-based memory device according to this embodiment includes five basic operations, namely, “data sensing”, “latching”, “writing into each sense amplifier circuit”, “erasing”, and “programming”, of the sense amplifier circuit of the semiconductor-based memory device according to this embodiment. First, a transition is made from the standby state to the basic operation for “data sensing”. Then, the basic operation for “latching” commences. The process up to this point is the same as that in the reading operation. Subsequently, the signal CLMP is lowered from the voltage V_{CLMP} to the ground level to disconnect the sense amplifier circuit and the bit line from each other. The basic operation for “writing into each sense amplifier circuit” is executed on the sense amplifier circuit, and at the same time, holes accumulated in the floating bodies of all memory cells connected to the selected word line are erased. In other words, the basic operation for “erasing” is executed. Then, while the disconnected state is maintained, the basic operation for “programming” is executed on the memory cells based on the data written in the sense amplifier circuit. During the basic operation for “erasing”, the word line activated during the basic operation for “data sensing” may be maintained at the voltage V_{WLR} in the basic operation for “data sensing”, or may be set to the voltage V_{WLW} in the basic operation for “programming” that follows thereafter.

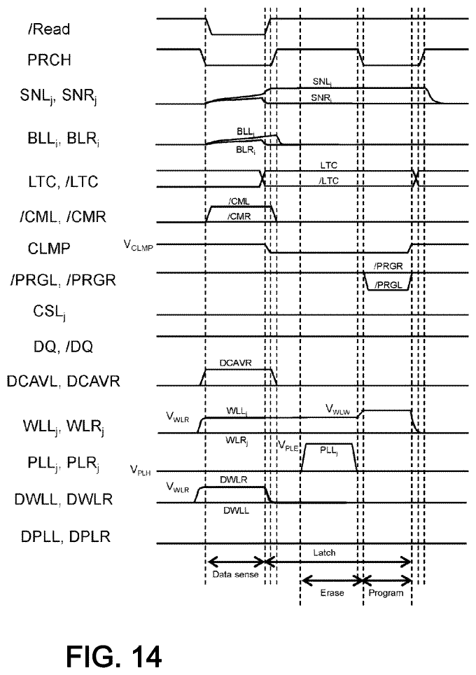

A refreshing operation of the semiconductor-based memory device according to this embodiment will now be described with reference to FIG. 14. This can be implemented by combining some of the basic operations of each sense amplifier circuit of the semiconductor-based memory device according to this embodiment. The refreshing operation of the semiconductor-based memory device according to this embodiment includes four basic operations, namely, “data sensing”, “latching”, “erasing”, and “programming”, of the sense amplifier circuit of the semiconductor-based memory device according to this embodiment. First, a transition is made from the standby state to the basic operation for “data sensing”. Then, the basic operation for “latching” commences. The process up to this point is the same as that in the reading operation. Subsequently, the signal CLMP is lowered from the voltage V_{CLMP} to the ground level to disconnect the sense amplifier circuit and the bit line from each other, and holes accumulated in the floating bodies of all memory cells connected to the selected word line are erased (the basic operation for “erasing”). Then, while the disconnected state is maintained, the basic operation for “programming” is executed on the memory cells based on the data latched in the sense amplifier circuit. The refreshing operation of the semiconductor-based memory device according to this embodiment is the same as the writing operation of the semiconductor-based memory device according to this embodiment except that there is no basic operation for “writing into each sense amplifier circuit” in the sense amplifier circuit of the semiconductor-based memory device according to this embodiment.

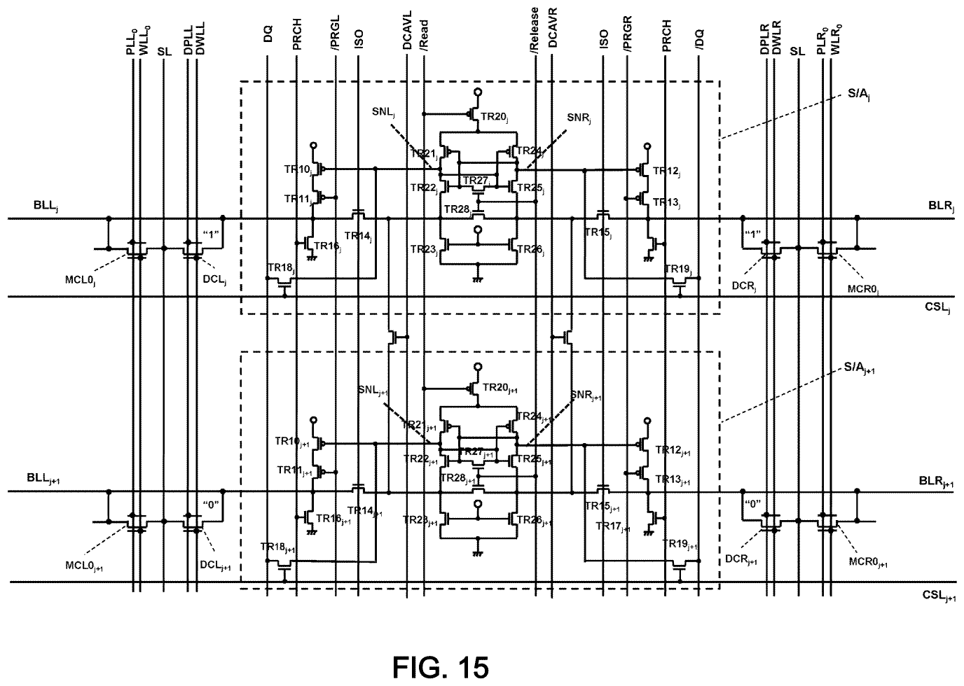

Another more specific circuit configuration of the memory cells and the sense amplifier circuits of the semiconductor-based memory device according to this embodiment will now be described with reference to FIG. 15. This is a specific example of each sense amplifier circuit in which the current load circuit block and the latch circuit block in FIG. 4 have been merged together. When the signal/Read reaches the ground level, electric current starts to flow through the memory cells and the dummy cells. At this time, a signal/Release is still at the power-supply voltage V_{dd} level, and the sense nodes SNLⱼ, SNRⱼ, SNLⱼ₊₁, and SNRᵢ₊₁ all settle at the same level (i.e., at a value between 0 V and V_{dd}). Then, when the signal/Release is lowered to the ground level, positive feedback acts between cross-coupled inverters so that a potential difference is developed and latched between the sense node pair SNLⱼ, SNRⱼ and the sense node pair SNLⱼ₊₁, SNRⱼ₊₁. Other basic operations, such as “erasing”, “programming”, “reading from each sense amplifier circuit”, and “writing into each sense amplifier circuit”, are similar to those in FIG. 4.

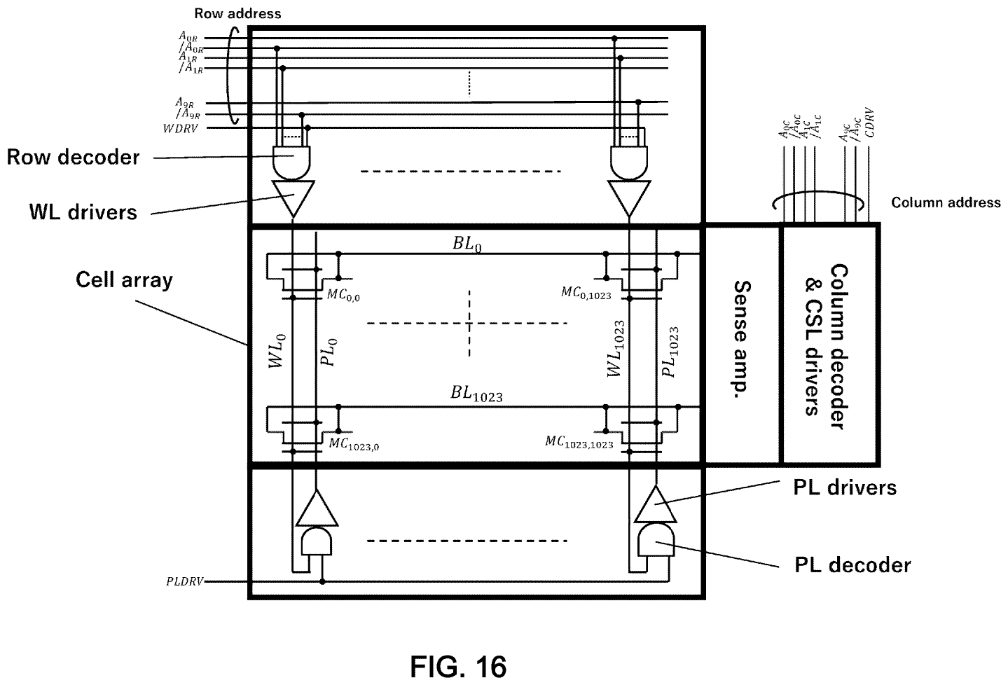

Each plate-line-PL driver circuit of the semiconductor-based memory device with a capacity of 1 Mbit (1024 bit by 1024 bit) according to this embodiment will now be described with reference to FIG. 16. A plate line PL to be activated when data is to be erased belongs to the selected word line WL. Therefore, the plate line PL may be selectively driven by the same row decoder as that of a word-line-WL driver circuit. However, this row decoder leads to a waste of circuit area since it is the same circuit as the row decoder for selectively driving the word line WL. As illustrated in FIG. 16, the word line WL itself is used as a selection signal, so that redundant circuits can be avoided. Specifically, as illustrated in FIG. 16, the plate line PL is driven by a logical product of the word line WL and a signal PDRV defining the timing for activating the plate line PL during data erasure, so that a more compact memory device can be provided. Needless to say, since the voltage of the word line and the voltage of the plate line are normally different from each other, a voltage conversion circuit has to be provided between the input of the word line and the plate-line-PL driver circuit. However, such a voltage conversion circuit is omitted in FIG. 16. FIG. 16 also does not illustrate dummy word lines, dummy cells connected thereto, selector and driver circuits for the dummy word lines, plate lines of the dummy cells, selector and driver circuits therefor, and so on.

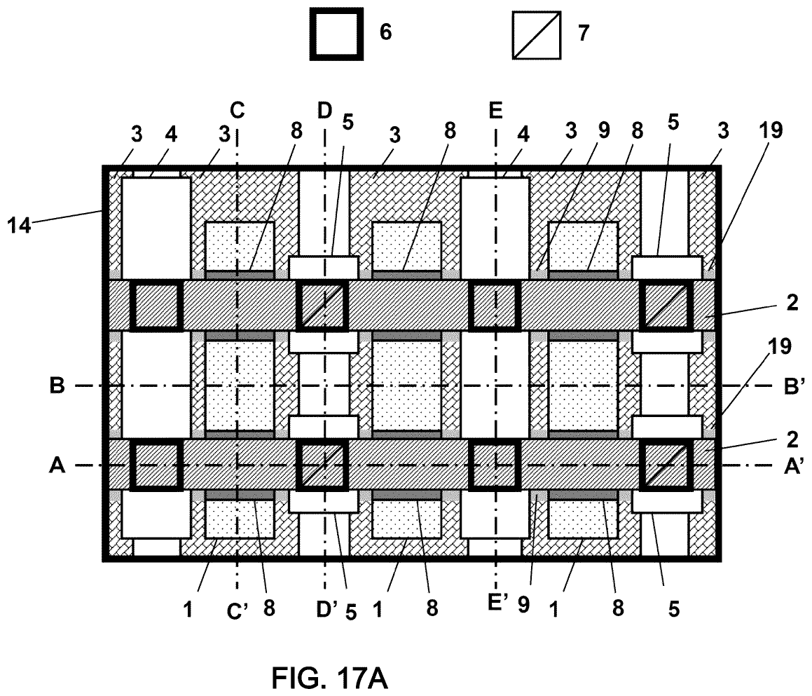

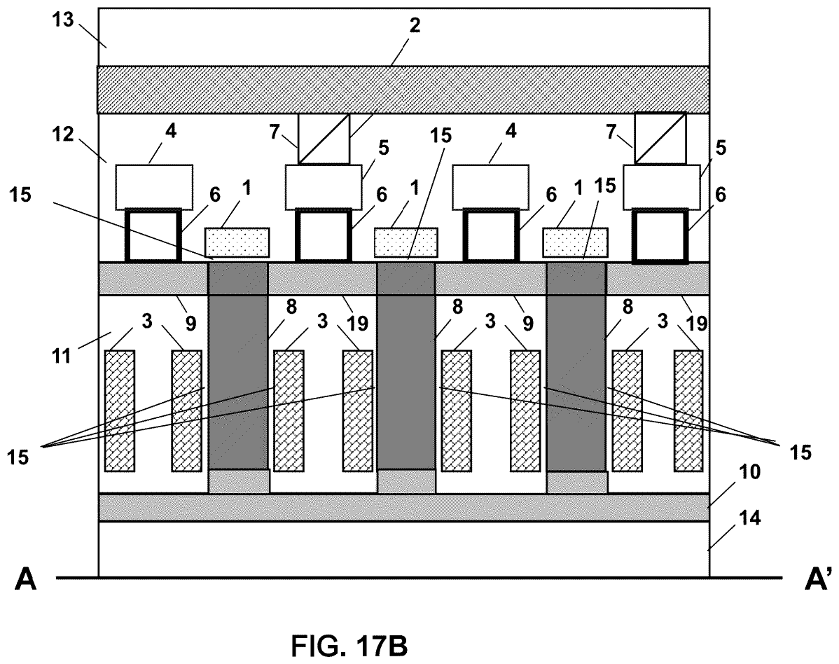

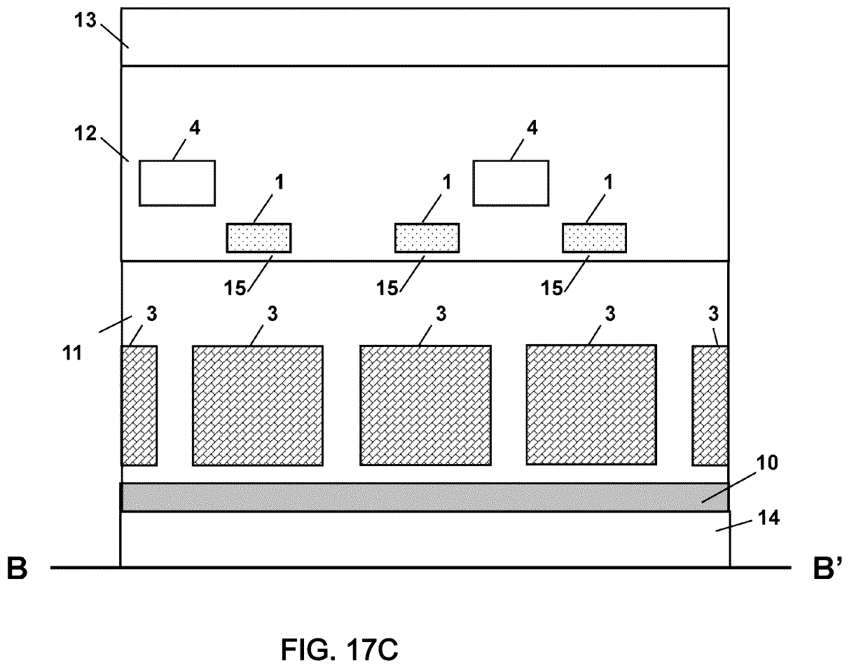

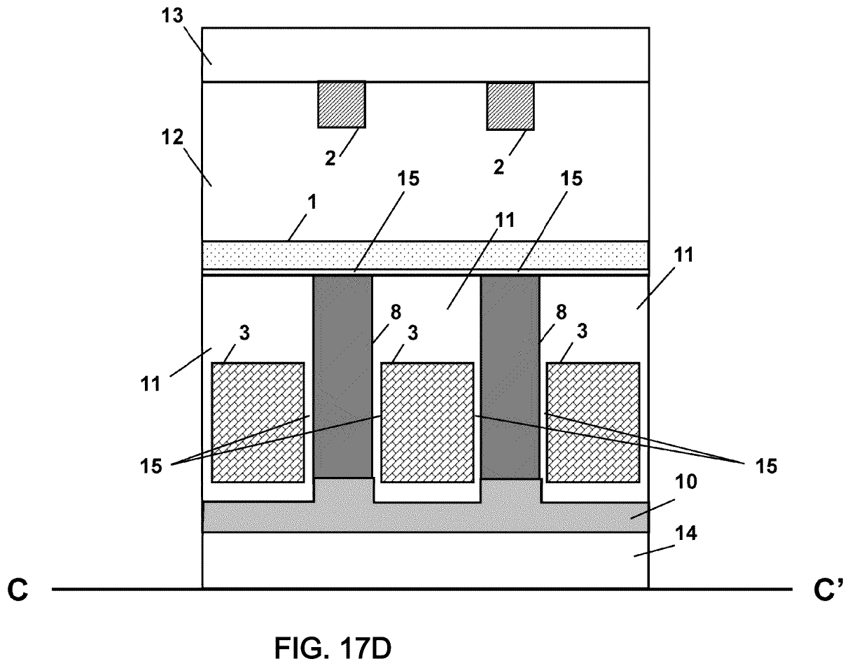

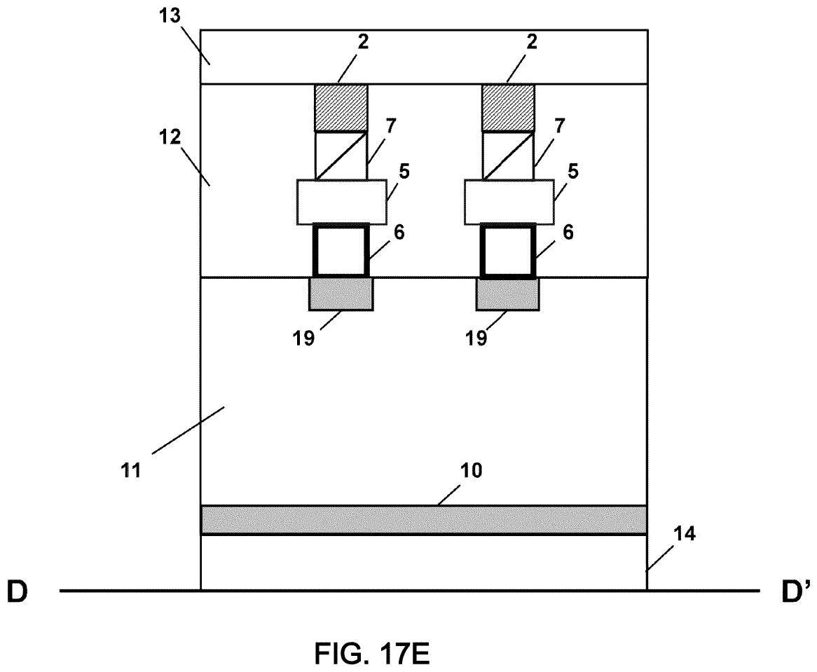

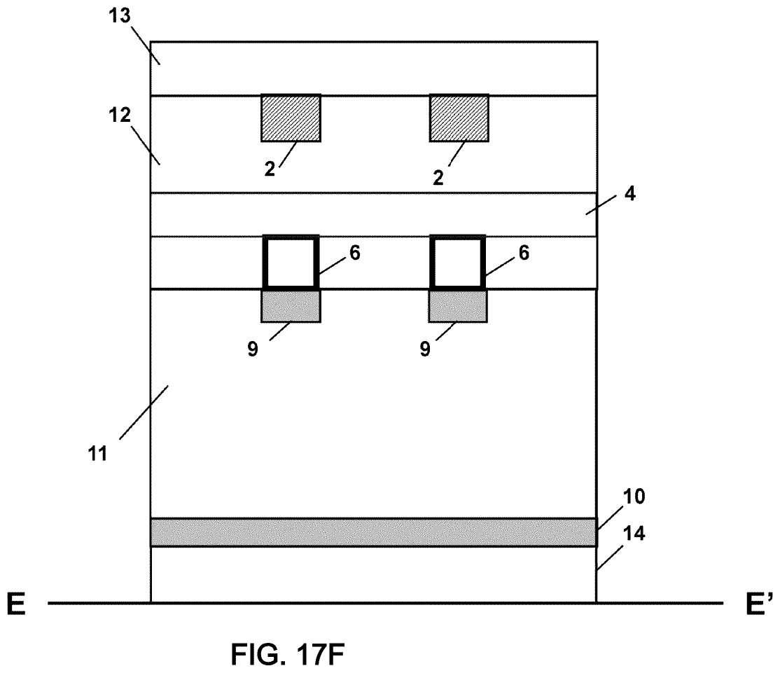

A device structure of memory cells of the semiconductor-based memory device according to this embodiment will now be described with reference to FIG. 17A to FIG. 17F. FIG. 17A is a plan view illustrating a cell structure of the semiconductor-based memory device according to this embodiment. In FIG. 17A, six memory cell regions corresponding to three word lines and two bit lines are illustrated within a cell array having memory cells arranged in a matrix. These six memory cell regions correspond to six memory cells where an equivalent circuit is indicated in an array to the left or right of the sense amplifier circuits in FIG. 1. FIG. 17B is a cross-sectional view taken along line AA′ in the plan view of FIG. 17A. FIG. 17C is a cross-sectional view taken along line BB′ in the plan view of FIG. 17A. FIG. 17D is a cross-sectional view taken along line CC′ in the plan view of FIG. 17A. FIG. 17E is a cross-sectional view taken along line DD′ in the plan view of FIG. 17A. FIG. 17F is a cross-sectional view taken along line EE′ in the plan view of FIG. 17A.

It is apparent from FIG. 17A, FIG. 17B, and FIG. 17E that first semiconductor regions 8 (e.g., a semiconductor body in the claims) corresponding to respective memory cells are arranged in a two-dimensional array above a p-type silicon substrate 14 (e.g., a substrate in the claims) and a second semiconductor region 10 located thereon and composed of n-type silicon. Each first semiconductor region 8 has impurity atoms (e.g., boron atoms) ion-implanted therein to become p-type silicon. N-type first impurity regions 9 (e.g., one of n-type second impurity regions in the claims) and 19 (e.g., another one of the n-type second impurity regions in the claims) that are in contact with an upper portion of each first semiconductor region 8 are disposed at opposite sides of the first semiconductor region 8 in the horizontal direction in FIG. 1. N-type silicon can be realized by ion-implanting, for example, phosphorus atoms.

It is apparent from FIG. 17A to FIG. 17F that second gate conductor layers (plate lines) 3 extend in the vertical direction in FIG. 17A to cover the first semiconductor regions 8, and are isolated by thin gate insulating films 15 (e.g., a gate insulating film in the claims). A first insulating layer 11 is embedded in a region below the upper surfaces of the n-type first impurity regions 9 and above the n-type second semiconductor region 10, except for the first semiconductor regions 8, the second gate conductor layers (plate lines) 3, and the gate insulating films 15 therebetween.

It is apparent from FIG. 17A and FIG. 17B that a first gate conductor layer (word line) 1 extends in the vertical direction in FIG. 17A above each first semiconductor region 8 with the gate insulating film 15 interposed therebetween, so as to form an n-type metal-oxide semiconductor field-effect transistor (MOSFET) in which the n-type first impurity regions 9 and 19 serve as a source or drain, the first semiconductor region 8 serves as a body, and the first gate conductor layer serves as a gate. As mentioned above, the gate insulating film 15 is disposed above (i.e., on the upper surface of) each first semiconductor region 8 and has a function for electrically insulating the first semiconductor region 8 and the first gate conductor layer (word line) 1 from each other. The gate insulating film 15 is also disposed to cover the side surfaces of each first semiconductor region 8 and has a function for electrically insulating the second gate conductor layer (plate line) 3 and the first semiconductor region 8 from each other. Each gate insulating film 15 may be disposed continuously and integrally with the side surfaces and the upper portion (upper surface) of the corresponding first semiconductor region 8, or may be disposed as a separate component. One of the source and the drain is connected to a first metal wiring layer (source line) 4 via a contact hole 6, and the first metal wiring layer (source line) 4 extends in the vertical direction in FIG. 17A. The other one of the source and the drain is connected to a second metal wiring layer (bit line) via the contact hole 6, a buffer layer 5 made of the same layer as the first metal wiring layer, and a via 7, and the second metal wiring layer (bit line) extends in the horizontal direction in FIG. 17A. A second insulating layer 12 is embedded in a region below the upper surface of the second metal wiring layer (bit lines) and above the upper surface of the n-type first impurity regions 9 and 19 except for the first gate conductor layers (word lines) 1, the gate insulating films 15 located therebelow, the contact holes 6, the first metal wiring layers (source lines), the buffer layer 5, the vias 7, and the second metal wiring layer (bit lines). A region above the upper surface of the second metal wiring layer (bit lines) is covered by a third insulating film 13.

The first embodiment of the present invention has the following features.

### Feature 1

As described with reference to FIG. 4, the semiconductor-based memory device according to the first embodiment of the present invention has plate lines isolated for respective word lines and extending parallel to the word lines, and can remove holes from the floating bodies of all memory cells along a selected word line. Regardless of this non-selective erasing operation, the memory device according to this embodiment can execute random writing and refreshing operations. This non-selective erasing operation is advantageous in that the word lines do not have to be set to a negative potential. Specifically, the issue of “1” disturb on the bit lines can be mitigated, so that the data retention characteristics of each cell can be improved.

### Feature 2

As described with reference to FIG. 4, the basic operation for “erasing” with respect to a memory cell and the basic operation for writing into a sense amplifier circuit can be executed concurrently in a state where the sense amplifier circuit and the bit line are disconnected from each other, so that the cycle time of the writing operation can be shortened.

### Feature 3

As described with reference to FIG. 16, in the semiconductor-based memory device according to the first embodiment of the present invention, the plate-line driver circuits can be disposed opposite the word-line driver circuits relative to the cell array. Consequently, a semiconductor memory device with a small chip area can be achieved.

### Second Embodiment

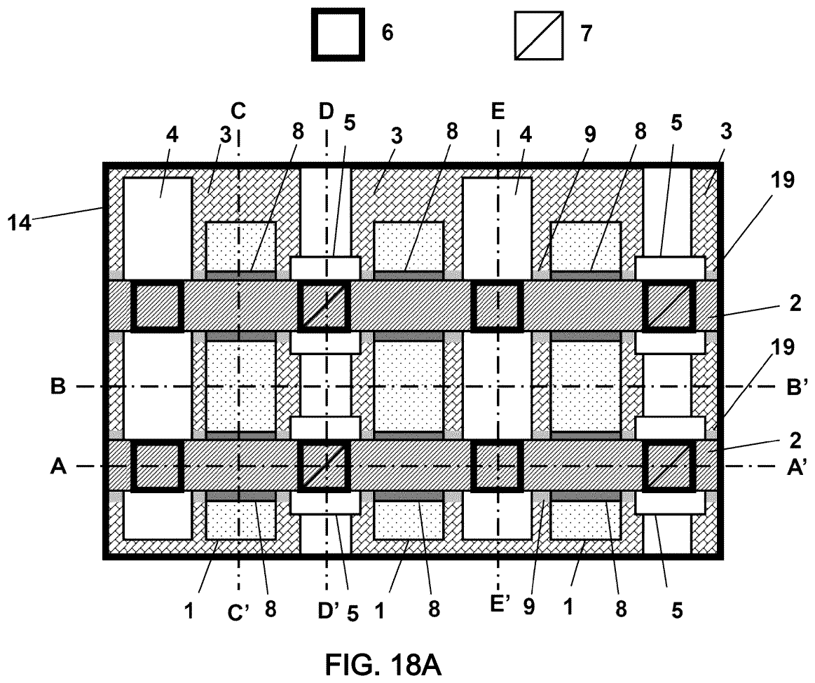

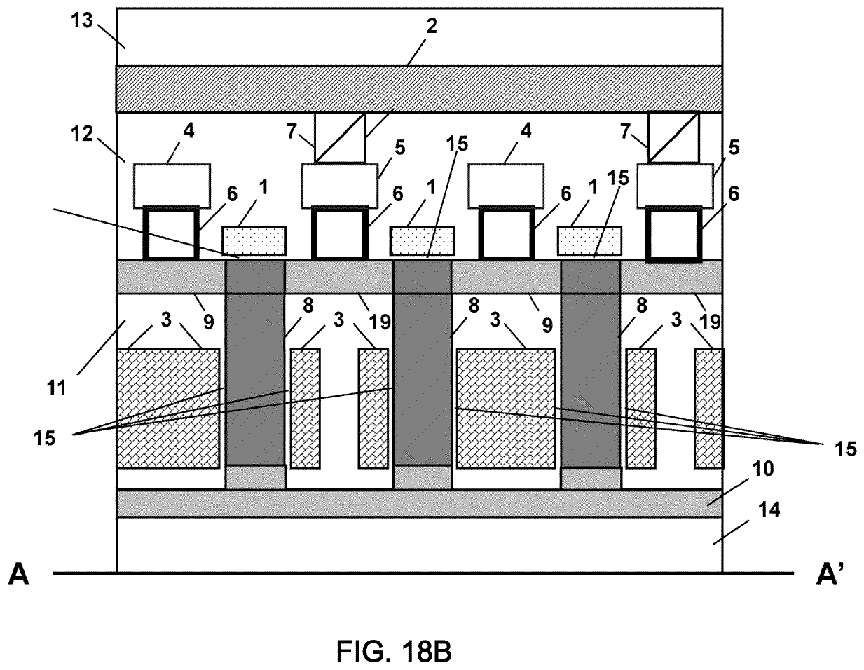

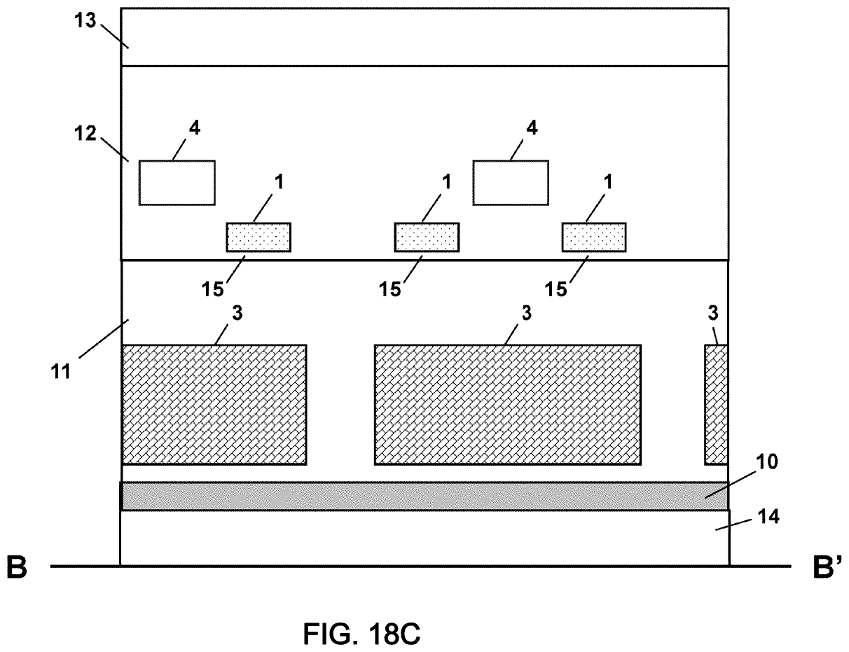

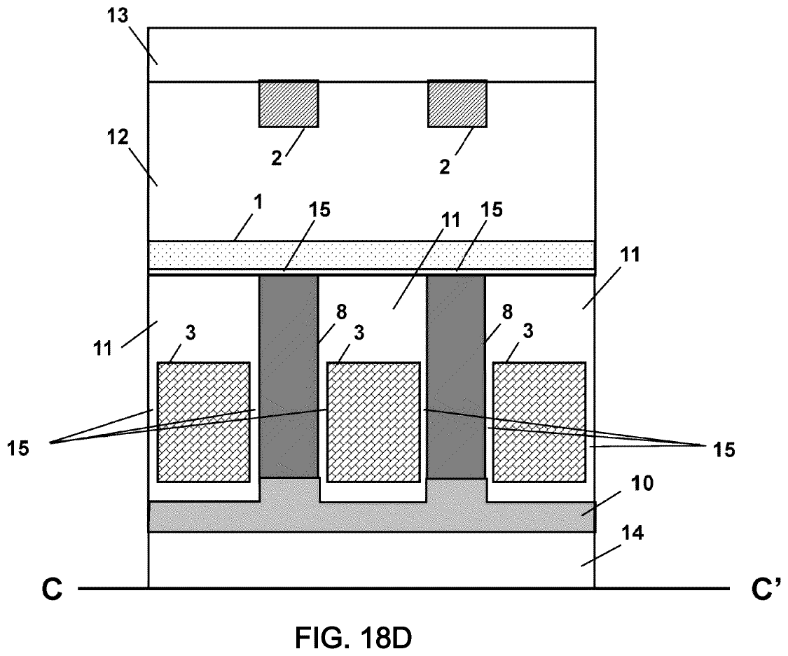

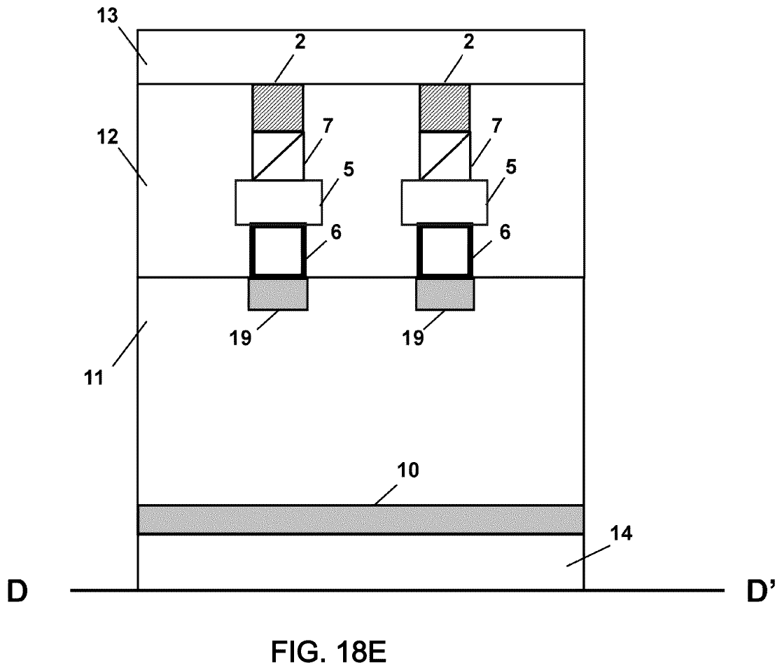

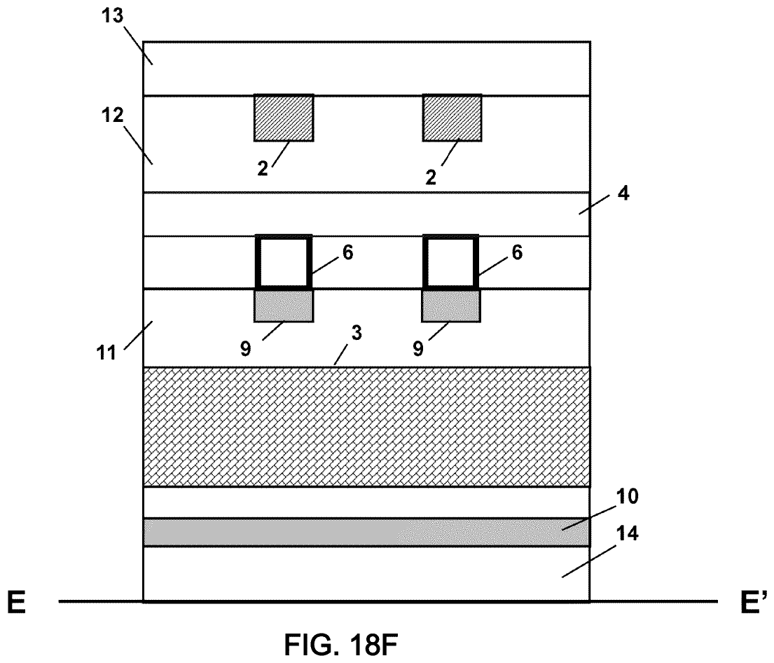

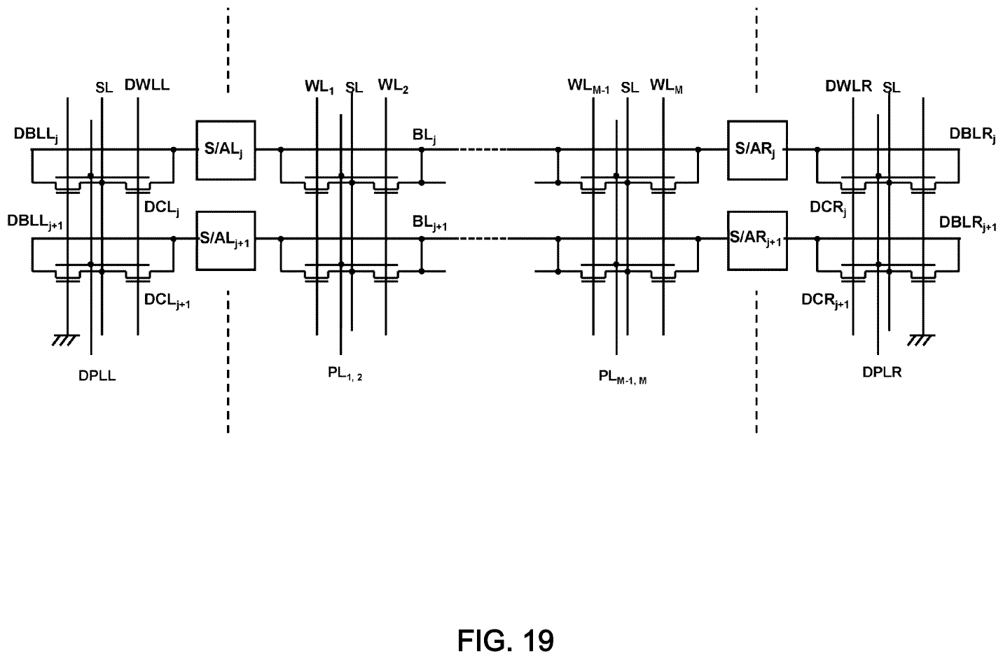

The structure of a semiconductor-based memory device according to this embodiment will now be described with reference to FIG. 18A to FIG. 18F and FIG. 19. FIG. 18A is a plan view illustrating a cell structure of the semiconductor-based memory device according to this embodiment. FIG. 18B is a cross-sectional view taken along line AA′ in the plan view of FIG. 18A. FIG. 18C is a cross-sectional view taken along line BB′ in the plan view of FIG. 18A. FIG. 18D is a cross-sectional view taken along line CC′ in the plan view of FIG. 18A. FIG. 18E is a cross-sectional view taken along line DD′ in the plan view of FIG. 18A. FIG. 18F is a cross-sectional view taken along line EE′ in the plan view of FIG. 18A. FIG. 19 illustrates a cell-array equivalent circuit of the semiconductor-based memory device according to this embodiment.

The cell structure of the semiconductor-based memory device according to this embodiment illustrated in FIG. 18A to FIG. 18F is the same as the cell structure of the semiconductor-based memory device according to the first embodiment except for the structure of the second gate conductor layers (plate lines) 3. In contrast to the cell structure of the semiconductor-based memory device according to the first embodiment illustrated in FIG. 17A to FIG. 17F in which each second gate conductor layer (plate line) 3 is disposed in an isolated fashion for every first gate conductor layer (word line 1), each second gate conductor layer (plate line) 3 in the cell structure of the semiconductor-based memory device according to this embodiment illustrated in FIG. 18A to FIG. 18F is disposed in an isolated fashion for every two adjacent first gate conductor layers (word lines) 1. The cell structure of the semiconductor-based memory device according to this embodiment and the cell structure of the semiconductor-based memory device according to the first embodiment are identical to each other except for this difference.

FIG. 19 illustrates cell-array equivalent circuits of the semiconductor-based memory device according to this embodiment as well as the relationship between the cell-array equivalent circuits and the sense amplifier circuits. In FIG. 19, sense amplifier circuits S/ALⱼ, S/ARⱼ and sense amplifier circuits S/ALⱼ₊₁, S/ARⱼ₊₁ are respectively disposed at opposite ends of two adjacent bit lines BLⱼ and BLⱼ₊₁. Dummy bit lines DBLLⱼ, DBLLⱼ₊₁ are disposed to the left of the left sense amplifier circuits, and are connected to dummy cells DCLⱼ, DCLⱼ₊₁ selected by a dummy word line DWLL and driven by a dummy plate line DPLL. Likewise, dummy bit lines DBLRⱼ, DBLRⱼ₊₁ are disposed to the right of the right sense amplifier circuits, and are connected to dummy cells DCRⱼ, DCRⱼ₊₁ selected by a dummy word line DWLR and driven by a dummy plate line DPLR. The sense amplifier circuits are the same as those illustrated in FIG. 4 or FIG. 5. However, the MOSFETS TR4ⱼ, TR5ⱼ, TR4ⱼ₊₁, and TR5ⱼ₊₁ are not necessary, and a common gate node of the MOSFETS TR2ⱼ and TR3ⱼ or TR2ⱼ₊₁ and TR3ⱼ₊₁ may be directly connected to the sense node SNLⱼ or SNRⱼ or to the sense node SNLⱼ₊₁ or SNRⱼ₊₁. In detail, the left sense amplifier circuits may be connected to the sense nodes SNL, and the right sense amplifier circuits may be connected to the sense nodes SNR. Furthermore, only one of the transistors TR20 and TR21 illustrated in FIG. 5 is required. In detail, the transistor TR21 is not required in the case of the left sense amplifier circuits, and the transistor TR20 is not required in the case of the right sense amplifier circuits.

The basic operations for data sensing and latching by the sense amplifier circuits are as follows. Assuming that an odd-numbered word line is selected, data stored in a cell connected thereto is data-sensed and latched by the left sense amplifier circuits S/ALⱼ and S/ALⱼ₊₁. In this case, the dummy word line DWLL is activated so that data is read from each of the dummy cells DCLⱼ and DCLⱼ₊₁. The data stored in the dummy cell DCLⱼ and the data stored in the dummy cell DCLⱼ₊₁ are opposite data, and the left sense nodes of the sense amplifier circuits S/ALⱼ and S/ALⱼ₊₁ are electrically short-circuited by a transistor not illustrated in FIG. 19, so that an intermediate current of the electric current flowing through the “1” data cell and the electric current flowing through the “0” data cell flows through these nodes. By referring to these currents, the data in each memory cell selected on the aforementioned odd-numbered word line is sensed. Subsequently, an even-numbered word line that shares a source line with the selected word line is activated, and data stored in a cell connected thereto is data-sensed and latched by the left sense amplifier circuits S/ARⱼ and S/ARⱼ₊₁. In this case, the dummy word line DWLR is activated so that data is read from each of the dummy cells DCRⱼ and DCRⱼ₊₁. The data stored in the dummy cell DCRⱼ and the data stored in the dummy cell DCRiti are opposite data, and the right sense nodes of the sense amplifier circuits S/ARⱼ and S/ARⱼ₊₁ are electrically short-circuited by a transistor not illustrated in FIG. 19, so that an intermediate current of the electric current flowing through the “1” data cell and the electric current flowing through the “0” data cell flows through these nodes. By referring to these currents, the data in each memory cell selected on the aforementioned even-numbered word line is sensed. When an even-numbered word line is selected, a process identical to that described above may be executed in the reversed order.

The basic operation for programming involves activating an odd-numbered word line and performing programming based on a latch state of the left sense amplifier circuits S/ALⱼ and S/ALⱼ₊₁, and subsequently activating an even-numbered word line and performing programming based on a latch state of the left sense amplifier circuits S/ARⱼ and S/AR_{j+1.}

The basic operation for erasing involves raising a plate line mutually disposed with respect to the aforementioned odd-numbered and even-numbered word lines to the positive potential V_{PLE} and removing holes from the floating bodies of all memory cells selected on these two word lines.

The operation for reading from each sense amplifier circuit involves activating the column select line CSLⱼ or CSLⱼ₊₁ to select the sense amplifier circuits S/AL; and S/ALⱼ₊₁ or S/ARⱼ and S/ARⱼ₊₁, and subsequently reading data to the common data line pair DQ, /DQ from the sense amplifier circuits S/ALⱼ and S/ALⱼ₊₁ or S/ARⱼ and S/ARⱼ₊₁ depending on whether a word line WL selected based on an address is odd-numbered or even-numbered.

The operation for writing into each sense amplifier circuit involves activating the column select line CSLⱼ or CSLⱼ₊₁ to select the sense amplifier circuits S/AL; and S/ALⱼ₊₁ or S/ARⱼ and S/ARⱼ₊₁, and subsequently writing data from the common data line pair DQ, /DQ, to the sense amplifier circuits S/ALⱼ and S/ALⱼ₊₁ or S/ARⱼ and S/ARⱼ₊₁ depending on whether a word line WL selected based on an address is odd-numbered or even-numbered.

Since the reading operation, the writing operation, and the refreshing operation of the semiconductor-based memory device according to this embodiment are executed similarly by using the basic operations, detailed descriptions will be omitted here.

In FIG. 18A to FIG. 18F and FIG. 19, a plate line (PL) is shared by two memory cells sharing a source line SL. Alternatively, a plate line (PL) may be shared by two memory cells sharing a bit line BL.

The second embodiment of the present invention has the following features.

### Feature 1

The semiconductor-based memory device according to the second embodiment of the present invention has a plate line isolated for every two word lines and extending parallel to the word lines, and can remove holes from the floating bodies of all memory cells along a selected word line and a word line adjacent thereto. Accordingly, the reading operation, the writing operation, and the refreshing operation can be executed. The semiconductor-based memory device according to the second embodiment of the present invention has such a structure so as to be capable of reducing the distance between two cells along a bit line relative to that in the first embodiment, whereby a semiconductor memory device with a further reduced bit cost can be provided.

### Feature 2

In the semiconductor-based memory device according to the second embodiment of the present invention, the positional relationship between the dummy cells and the sense node pairs is determined in advance, so that a transistor for switching the current mirror connection of the sense amplifier circuits is not required. In addition, in a circuit that generates a reference current by averaging the cell currents, the dummy cells are fixed to the sense amplifier circuits, so that one of averaging circuits is not required. Accordingly, the size of each sense amplifier circuit can be reduced relative to that in the first embodiment, whereby a semiconductor memory device with a further reduced bit cost can be provided.

The present invention can provide a semiconductor memory device with a higher density, higher speed, and higher operational margin than in the related art.

What is claimed is:

1. A semiconductor memory device comprising:
a plurality of memory cells arranged in a first direction on a substrate in plan view to constitute a page,
wherein each memory cell includes
an electrically-floating semiconductor body,
a first impurity region that is in contact with one of side surfaces of the semiconductor body and connects with a source line, and a second impurity region that is in contact with another one of the side surfaces of the semiconductor body and connects with a bit line,
a gate insulating film that is in contact with the semiconductor body,
a first gate conductor layer that forms a transistor together with the semiconductor body, the first impurity region, and the second impurity region and that is in contact with the gate insulating film and is connected to a word line, and
a second gate conductor layer that is in contact with the gate insulating film at a location different from the first gate conductor layer and that is connected to a plate line;
a sense amplifier circuit that amplifies and latches a signal read from the memory cell connected to the bit line via a first switching circuit; and
a data line connected to the sense amplifier circuit via a second switching circuit,
wherein a writing operation includes activating the word line and turning on the first switching circuit to cause the sense amplifier circuit to amplify and latch data stored in the memory cell, blocking the first switching circuit, selecting the plate line to erase the memory cell while simultaneously turning on the second switching circuit to input data from the data line to the sense amplifier circuit and change a latch state of the sense amplifier circuit, and subsequently programming the memory cell in accordance with the latch state of the sense amplifier circuit.

2. The semiconductor memory device according to claim 1,
wherein a refreshing operation includes
activating the word line and turning on the first switching circuit to cause the sense amplifier circuit to amplify and latch the data stored in the memory cell,
blocking the first switching circuit and selecting the plate line to erase the memory cell, and
subsequently programming the memory cell in accordance with the latch state of the sense amplifier circuit.

3. The semiconductor memory device according to claim 1,
wherein a word-line driver circuit connected to one end of the word line extending in the first direction in plan view is selectively activated by a row address selector circuit,
wherein a plate-line driver circuit connected to one end of the plate line is located in an opposite direction of a memory cell array from the word-line driver circuit relative to the first direction, and
wherein the plate-line driver circuit is selectively activated by the word line.

4. The semiconductor memory device according to claim 1,
wherein the sense amplifier circuit includes a first sense node isolated from a first bit line via a first switching element,
a second sense node that is located opposite the first bit line relative to the sense amplifier circuit or that is isolated from another second bit line adjacent to the first bit line via a second switching element,
a current load circuit that causes electric current to flow through the first and second bit lines via the first and second sense nodes and the first and second switching elements,
a latch circuit that amplifies and latches a potential difference between the first and second sense nodes,
a first programming circuit that applies voltage to the first bit line,
a second programming circuit that applies voltage to the second bit line,
a third switching element that lowers the first bit line to ground potential,
a fourth switching element that lowers the second bit line to ground potential,
a fifth switching element that connects the first sense node to one of common data lines, and
a sixth switching element that connects the second sense node to another one of the common data lines.

5. The semiconductor memory device according to claim 4, wherein the current load circuit and the latch circuit are an identical circuit.

6. The semiconductor memory device according to claim 4, further comprising:
a second sense amplifier circuit in addition to the sense amplifier circuit, the second sense amplifier circuit including
a third sense node isolated from a third bit line via a seventh switching element,
a fourth sense node that is located opposite the third bit line relative to the second sense amplifier circuit or that is isolated from another fourth bit line adjacent to the third bit line via an eighth switching element,
a current load circuit that causes electric current to flow through the third and fourth bit lines via the third and fourth sense nodes and the seventh and eighth switching elements,
a latch circuit that amplifies and latches a potential difference between the third and fourth sense nodes,
a third programming circuit that applies voltage to the third bit line,
a fourth programming circuit that applies voltage to the fourth bit line,
a ninth switching element that lowers the third bit line to ground potential,
a tenth switching element that lowers the fourth bit line to ground potential,
an eleventh switching element that connects the third sense node to one of the common data lines, and
a twelfth switching element that connects the fourth sense node to another one of the common data lines, and
wherein the first sense node of the sense amplifier circuit and the third sense node of the second sense amplifier circuit are electrically short-circuited by a thirteenth switching circuit, or
wherein the second sense node of the sense amplifier circuit and the fourth sense node of the second sense amplifier circuit are electrically short-circuited by a fourteenth switching circuit.

7. The semiconductor memory device according to claim 6,
wherein a first dummy cell having a structure identical to a structure of each memory cell is connected to the first bit line and a first dummy word line,
wherein a second dummy cell having a structure identical to the structure of each memory cell is connected to the second bit line and a second dummy word line,
wherein a third dummy cell having a structure identical to the structure of each memory cell is connected to the third bit line and the first dummy word line,
wherein a fourth dummy cell having a structure identical to the structure of each memory cell is connected to the fourth bit line and the second dummy word line,
wherein a stored state in the first dummy cell and a stored state in the third dummy cell are opposite to each other, and
wherein a stored state in the second dummy cell and a stored state in the fourth dummy cell are opposite to each other.

8. The semiconductor memory device according to claim 1,
wherein the semiconductor body is a first semiconductor region of a first conductivity type that is in an electrically floating state and that extends vertically in a columnar shape from a surface of the substrate,
wherein the first gate conductor layer is connected to an upper surface of the first semiconductor region via the gate insulating film,
wherein the second gate conductor layer is connected to a columnar section of the first semiconductor region via the gate insulating film,
wherein the first impurity region and the second impurity region are second semiconductor regions of a second conductivity type that are in contact with an upper side surface of the first semiconductor region and that are located at opposite sides thereof in a horizontal direction, and
wherein the source line serving as a first metal wiring layer is connected to the second semiconductor region corresponding to the first impurity region, the bit line serving as a second metal wiring layer is connected to the second semiconductor region corresponding to the second impurity region, the word line is connected to the first gate conductor layer, and the plate line is connected to the second gate conductor layer, is isolated for every word line, and is routed parallel to the word line.
